(19) United States
(12) Patent Application Publication
(10) Pub. No.: US 2010/0281289 A1
(43) Pub. Date: Nov. 4, 2010

(54) Bidirectional Memory Interface with Glitch Tolerant Bit Slice Circuits

(76) Inventors: Kun-Yung Chang, Los Altos, CA (US); Jie Shen, Fremont, CA (US); Hae-Chang Lee, Los Altos, CA (US); Fariborz Assaderaghi, Los Altos, CA (US); Richard E. Perego, Thornton, CO (US); Jung-Hoon Chun, Mountain View, CA (US)

Correspondence Address: MORGAN LEWIS & BOCKIUS LLP/RAMBUS INC., 2 PALO ALTO SQUARE, 3000 EL CAMINO REAL, SUITE 700, PALO ALTO, CA, 94306, US

(21) Appl. No.: 12/743,075

(22) PCT Filed: Nov. 14, 2008
(86) PCT No.: PCT/US2008/083626

§ 371 Date: May 14, 2010

Related U.S. Application Data
(60) Provisional application No. 60/989,788, filed on Nov. 21, 2007.

(51) Int. Cl. G06F 1/12; G06F 1/04; H03L 7/06; H03H 7/01; G06G 7/12

(52) U.S. Cl. 713/400; 713/503; 713/500; 327/147; 333/175; 327/355

(57) ABSTRACT

A bit slice circuit having transmit and receive modes of operation is described. The bit slice circuit comprises: first transmit circuitry and first receive circuitry operating in a first clock domain, wherein the first circuitry receives a first clock signal; second transmit circuitry and second receive circuitry operating in a second clock domain, wherein the second circuitry receives a second clock signal; transmit transition circuitry and receive transition circuitry, the transmit transition circuitry coupling the first transmit circuitry to the second transmit circuitry, the receive transition circuitry coupling the first receive circuitry to the second receive circuitry, wherein the transition circuitry receives the first and second clock signals; and a single phase mixer that generates the second clock signal, wherein the second clock signal has a first phase in the transmit mode of operation and second phase in the receive mode of operation.

### TECHNICAL FIELD

The subject matter disclosed herein relates generally to the field of communications and more particularly to high speed electronic signaling within a bidirectional memory interface.

### BACKGROUND

High speed controller memory interfaces, such as bidirectional memory interfaces, present significant engineering challenges. For example, in some bidirectional memory interfaces, independent clocks are needed for both transmit and receive operations, and thus, the number of phase mixers required for each bidirectional memory interface is doubled. This results in a large area and high power bidirectional memory interface.

### BRIEF DESCRIPTION OF THE DRAWINGS

FIGS. 1A-1C are block diagrams illustrating a controller in accordance with some embodiments.

FIG. 2A is a block diagram illustrating a bit slice circuit in accordance with some embodiments.

FIG. 2B is a block diagram illustrating a data path of a skip circuit of the bit slice circuit of FIG. 2A in accordance with some embodiments.

FIG. 2C illustrates an exemplary timing relationship of the signals in the skip circuit of FIG. 2B in accordance with some embodiments.

FIG. 3A is a block diagram illustrating a data path of a transmit transition circuit in accordance with some embodiments.

FIG. 3B is a block diagram illustrating a data path of a receive transition circuit in accordance with some embodiments.

FIG. 3C is a block diagram illustrating a configuration circuit for the transmit transition and receive transition circuitry in accordance with some embodiments.

FIG. 3D illustrates an exemplary timing relationship of the signals in the configuration circuit of FIG. 3C in accordance with some embodiments.

FIG. 3E illustrates an exemplary timing relationship of the signals in the transmit transition and receive transition circuitry of FIGS. 3A-3B in accordance with some embodiments.

FIGS. 4A-4B illustrate phase mixers in accordance with some embodiments.

FIGS. 5A-5E are flow diagrams of a process for increasing skip margin in a bit slice circuit with transmit and receive modes of operation in accordance with some embodiments.

FIG. 6 is a flow diagram of a process of increasing skip margin in a bidirectional memory interface in accordance with some embodiments.

FIG. 7 is a block diagram of an embodiment of a system for storing computer readable files containing software descriptions of circuits for implementing a bidirectional memory interface in accordance with some embodiments

Like reference numerals refer to corresponding parts throughout the drawings.

### DESCRIPTION OF EMBODIMENTS

A bit slice circuit has transmit and receive modes of operation. First transmit circuitry and first receive circuitry of the bit slice circuit operate in a first clock domain and receive a first clock signal. Second transmit circuitry and second receive circuitry of the bit slice circuit operate in a second clock domain and receive a second clock signal. Transmit transition circuitry couples the first transmit circuitry to the second transmit circuitry, and receive transition circuitry couples the first receive circuitry to the second receive circuitry. The transition circuitry receives both the first and second clock signals. Furthermore, the second clock signal has a first phase in the transmit mode of operation and second phase in the receive mode of operation.

A transceiver circuit includes first and second bit slice circuits, and a single locked loop circuit for generating a local master clock signal that has at least four clock phasors and that is coupled to phase mixers in both the first and second bit slice circuits.

A transceiver circuit has N bit slice pairs, where N is an integer greater than 1. Each bit slice pair includes first and second bit slice circuits and a single locked loop circuit for generating a reference clock signal that is coupled to phase mixers in both the first and second bit slice circuits. Furthermore, the N bit slice pairs transmit 2N bits in parallel, and receive 2N bits in parallel.

The amount of timing uncertainty that transition circuitry (sometimes called a skip circuit) can allow between two clock domains before incurring bit errors is called the skip margin. The design of such transition circuitry, between two high-speed (e.g., 8 GHz) clock domains that have an unknown phase relationship, is described in detail below. In some embodiments described below, the skip margin is half of a clock cycle of the clock signal (e.g., dclk) in one of the two clock domains. In a method of increasing skip margin in a bit slice circuit, with transmit and receive modes of operation, a first clock signal is received by first transmit circuitry and first receive circuitry, which operate in a first clock domain. A second clock signal is received second transmit circuitry and second receive circuitry, which operate in a second clock domain. Transmit transition circuitry and receive transition circuitry receive both the first and second clock signals. The transmit transition circuitry couples the first transmit circuitry and second transmit circuitry, and the receive transition circuitry coupled the first receive circuitry and second receive circuitry. The second clock signal is generated by a single phase mixer so as to have a first phase in the transmit mode of operation and a second phase in the receive mode of operation.

A method of increasing skip margin in a bidirectional memory interface includes generating a reference clock signal in a single locked loop circuit, the single locked loop circuit coupled to a first phase mixer in a first bit slice circuit and to a second phase mixer in a second bit slice circuit. The method also includes receiving the reference clock signal at the first phase mixer and the second phase mixer.

Reference will now be made in detail to embodiments, examples of which are illustrated in the accompanying drawings. In the following detailed description, numerous specific details are set forth in order to provide a through understanding of the present invention. It will be apparent, to one of ordinary skilled in the art, however, that the present invention may be practiced without these specific details. In other instances, well-known methods, procedures, components, and circuits have not been described in detail so as not to unnecessarily obscure aspects of the embodiments.

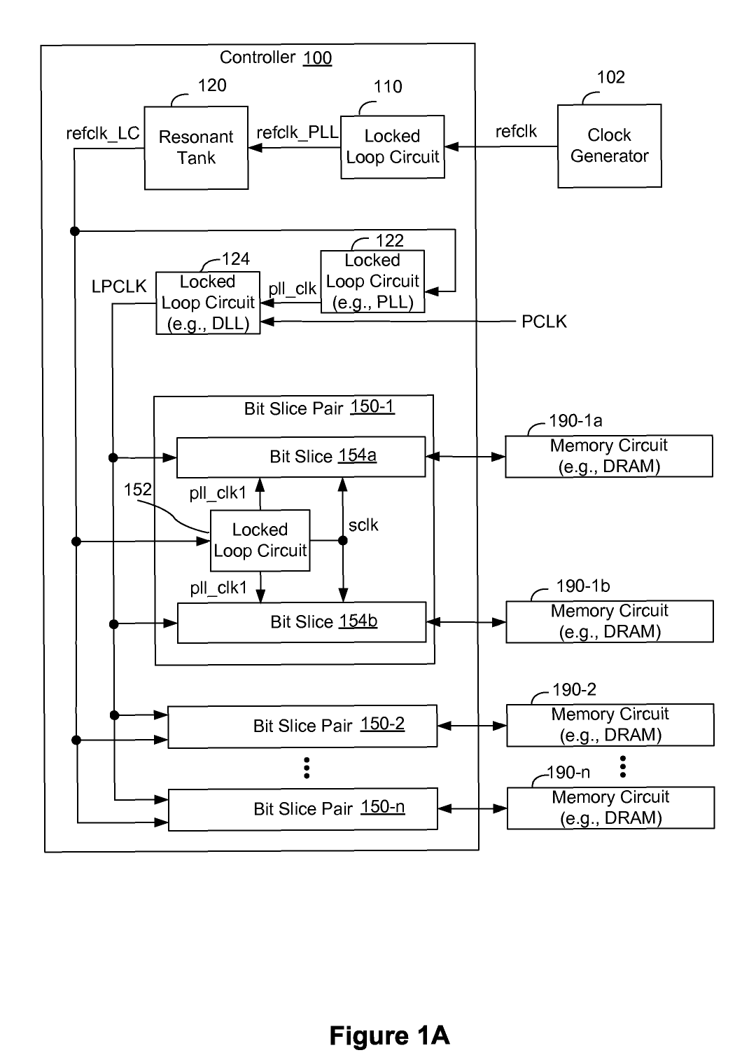

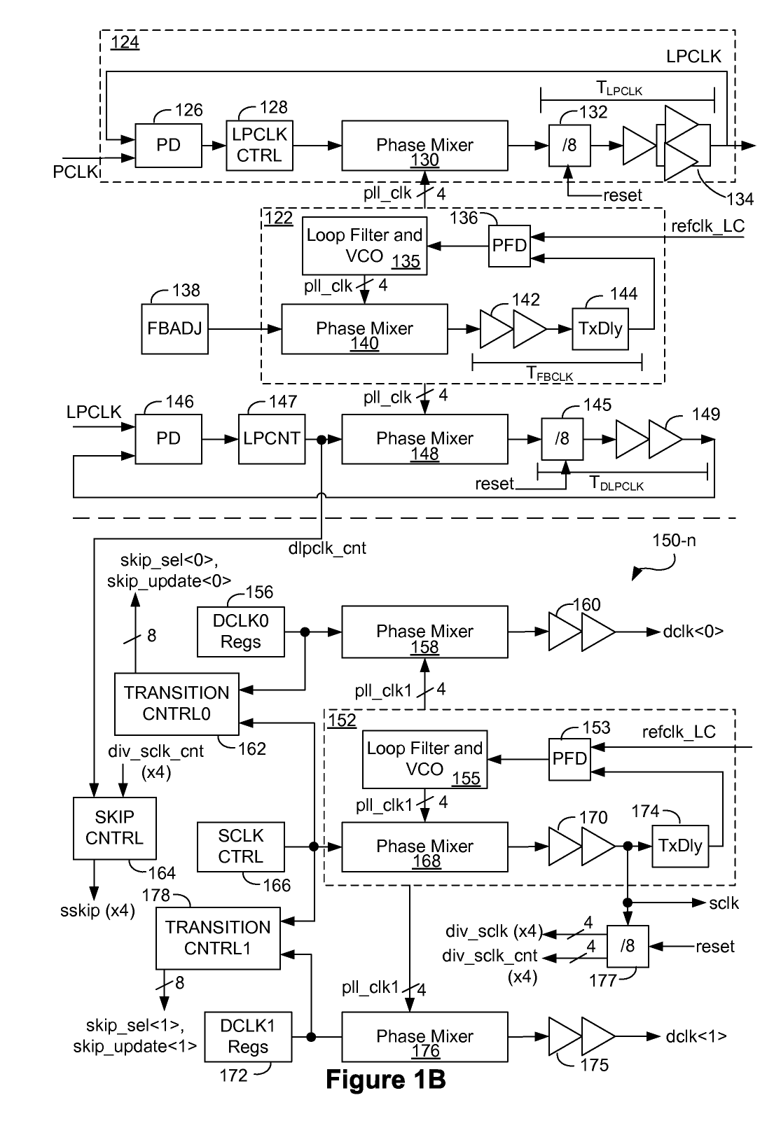

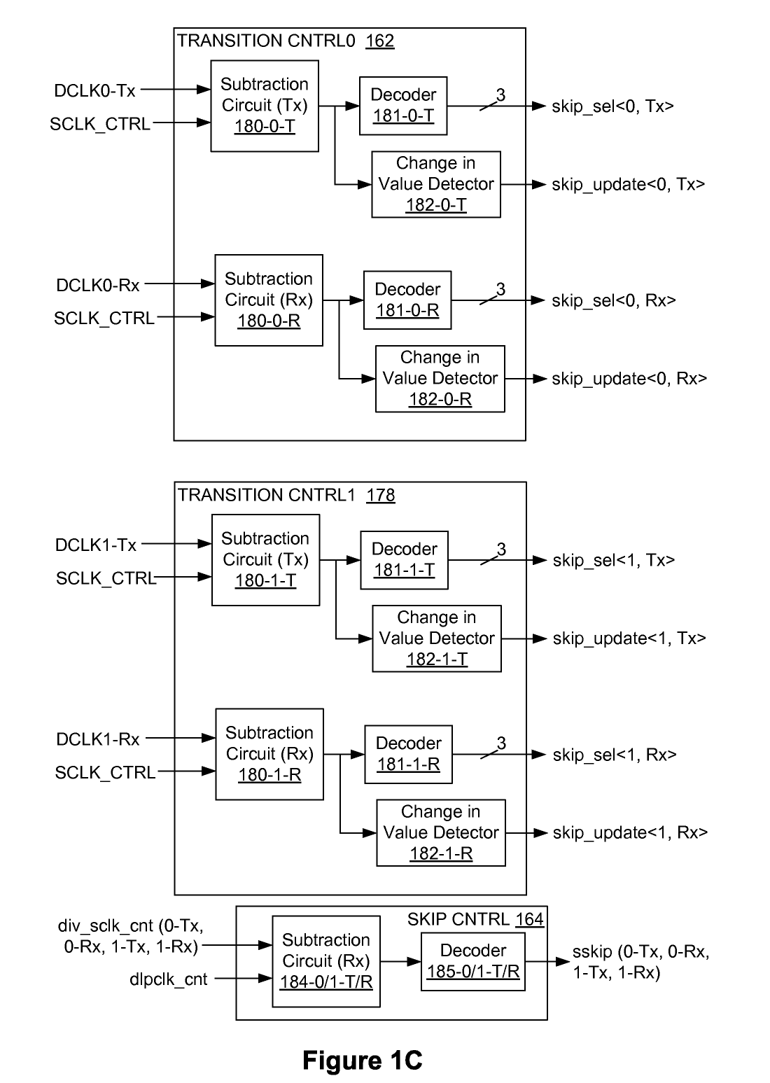

As shown in FIG. 1A, a controller 100 includes a plurality of locked loop circuits 110, 124 and 122, and a plurality of bit slice pairs 150-1, 150-2, . . . 150-n. In some embodiments, the controller 100 includes a resonant tank circuit 120. The controller 100 is coupled to a plurality of memory circuits 190-1, 190-2, . . . 190-n via the plurality of bit slice pairs 150-1, 150-2 . . . 150-n. For example, bit slice pair 150-1 is coupled to memory circuit 190-1, bit slice pair 150-2 is coupled to 190-2, and bit slice pair 150-n is coupled to memory circuit 190-n. In some embodiments, memory circuits 190-1, 190-2, . . . 190-n include high-speed random access memory, such as DRAM, SRAM, DDR RAM, MRAM or other random access solid state memory devices; and may include non-volatile memory, such as one or more magnetic disk storage devices, optical disk storage devices, flash memory devices, or other non-volatile solid state storage devices.

The controller 100 receives a reference clock signal (refclk) from a clock generator 102. In some embodiments, refclk has a frequency of 500 MHz. In some embodiments, the clock generator 102 is located external to the controller 100 while in other embodiments the clock generator 102 is in the controller 100.

The locked loop circuit 110 receives refclk from the clock generator 102. In some embodiments, the loop circuit 110 is a phase locked loop (PLL). The locked loop circuit 110 uses refclk to generate a controller clock signal (refclk_PLL) that is used by the controller 100 to transmit data to and receive data from memory circuits 190-1, 190-2, . . . 190-n. Refclk_PLL has a frequency that is a multiple (e.g., an multiple that is greater than one) of the frequency of refclk and is used to set the operating frequency of the controller 100. The locked loop circuit 110 may also clean-up a portion of the jitter in refclk. In some embodiments, the operating frequency of the controller is 8 GHz.

In some embodiments, the resonant tank circuit 120 receives refclk_PLL from the locked loop circuit 110 and distributes a version of refclk_PLL (refclk_LC) to the plurality of bit slice pairs 150-1, 150-2 . . . 150-n. The resonant tank circuit 120 may include one or more inductors (not shown) and capacitors (not shown). These inductors and capacitors may be either intentional or parasitic. In some embodiments, the resonant tank circuit 120 has a resonant frequency (e.g., 8 GHz) equal to the operating frequency of the controller 100.

The locked loop circuits 124 and 122 generate a local processor clock signal (LPCLK) to be used in the plurality of bit slice pairs 150-1, 150-2 . . . 150-n. In various embodiments, LPCLK has a frequency of 1 GHz, the locked loop circuit 122 is a phase locked loop (PLL), and/or the locked loop circuit 124 is a delay-locked loop (DLL). The locked loop circuit 124 receives a clock signal (pll_clk) from locked loop circuit 122 and a processor clock signal (PCLK) from an external source, such as a PLL (not shown) used in a processor or an application-specific integrated circuit (ASIC) coupled to the controller 100. In some embodiments, pll_clk is comprised of four clock phasors. The locked loop circuits 124 and 122 are discussed below in relation to FIG. 1B.

In some embodiments, the bit slice pairs 150-1, 150-2, . . . 150-n receive refclk_PLL from the locked loop circuit 110, while in other embodiments the bit slice pairs 150-1, 150-2, . . . 150-n receive refclk LC from the resonant tank circuit 120. In addition, in some of these embodiments the plurality of bit slice pairs 150-1, 150-2, . . . 150-n receive LPCLK from locked loop circuits 124 and 122.

Each of the bit slice pairs 150-1, 150-2, . . . 150-n includes a locked loop circuit 152, a first bit slice 154a and a second bit slice 154b. Each of the bit slice pairs 150-x may be considered to be a transceiver circuit. Alternately, the plurality of bit slice pairs 150-x may be considered to be a transceiver circuit that transmits 2N bits in parallel, and receives 2N bits in parallel. In some embodiments, the locked loop circuit 152 is positioned equidistantly from the first bit slice 154a and the second bit slice 154b. In some embodiments, the locked loop circuit 152 is positioned symmetrically with respect to the first bit slice 154a and the second bit slice 154b. The first bit slice 154a is coupled to a first memory circuit 1901-1a and the second bit slice 154b is coupled to a second memory circuit 190-1b. In some embodiments, the first bit slice 154a and the second bit slice 154b transmit or receive data in parallel.

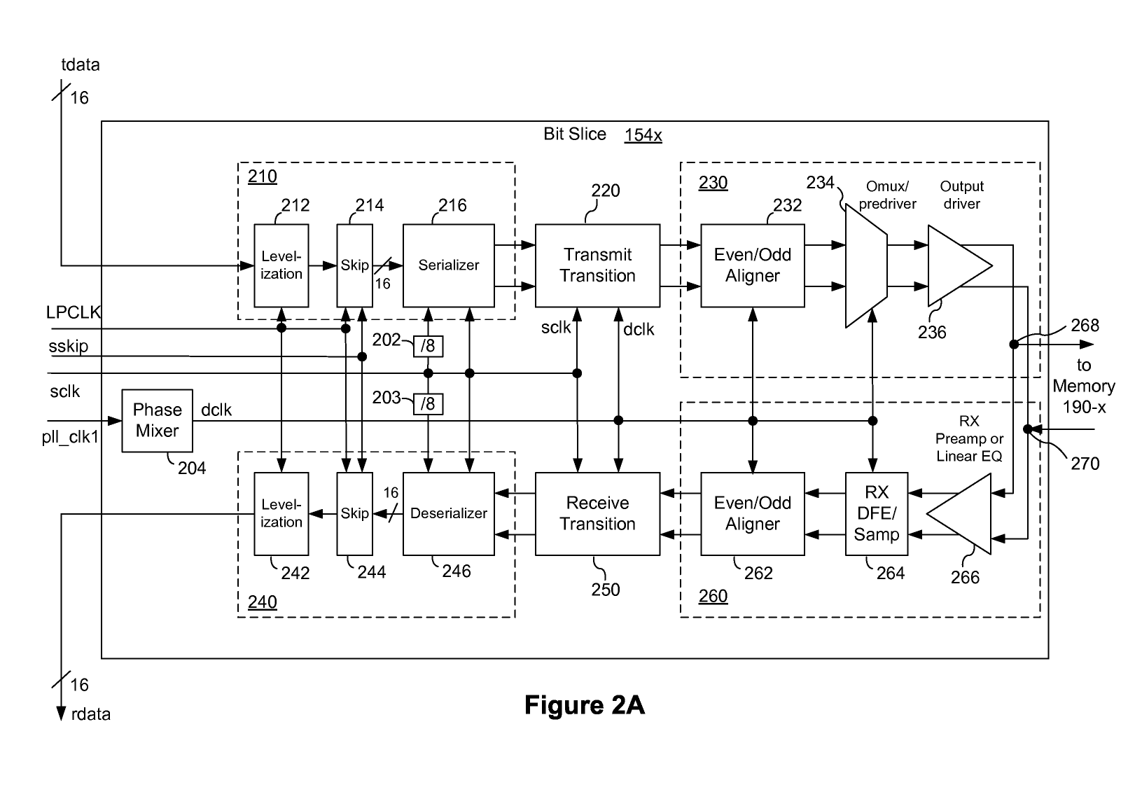

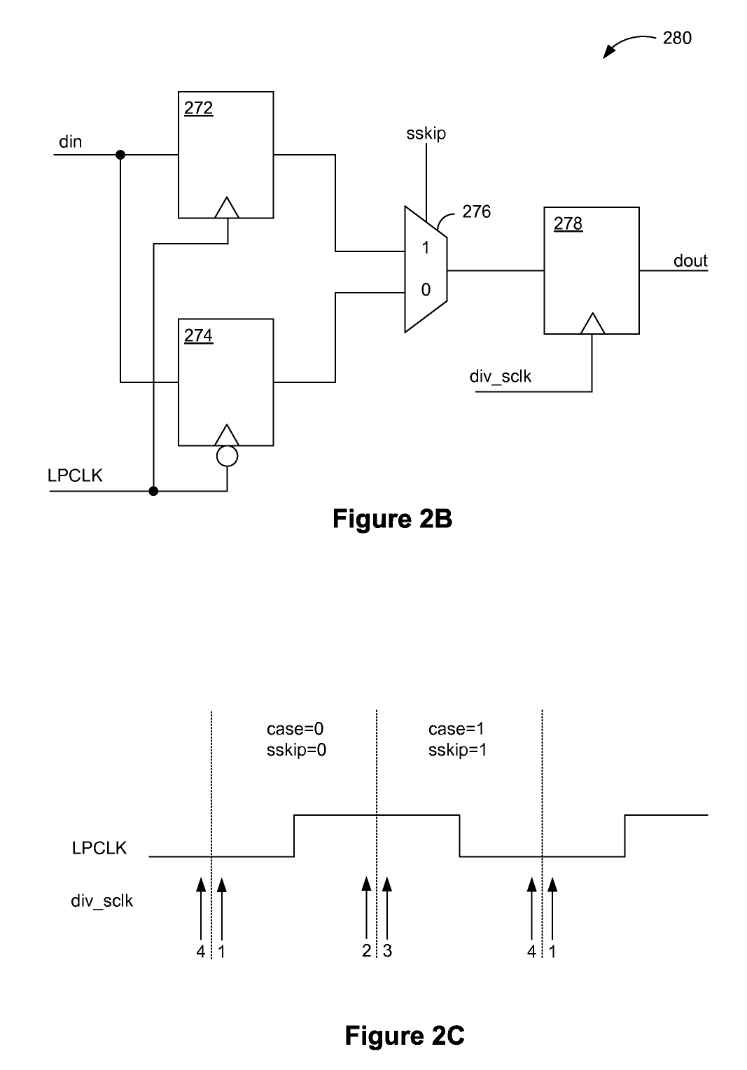

In some embodiments, the first bit slice 154a and the second bit slice 154b are identical, or substantially identical (e.g., they may have slightly different circuit layouts, or slightly different circuit parameters due to process variations that occur during manufacture), and thus, for simplicity are sometimes referred to hereinafter in this document as bit slice 154x. Bit slice 154x is discussed below in relation to FIG. 2A.

The locked loop circuit 152 (e.g., a PLL) generates a first clock signal (pll_clk1) and a second clock signal (sclk) for use by the two bit slices 154a, 154b of a bit slice pair 150. In some embodiments, the first clock signal, pll_clk1, is comprised of four clock phasors. In some embodiments, the second signal, sclk, is used to clock “internal” portions of the bit slice 154a or 154b and has the same phase in both the transmit and receive modes of operation.

In some embodiments, the locked loop circuit 152 receives refclk_PLL from the locked loop circuit 110. Alternately, in the embodiment shown in FIG. 1A, the locked loop circuit 152 receives refclk_LC from the resonant tank circuit 120. The locked loop circuit 152 is discussed below in relation to FIG. 1B.

As stated above and as shown in FIG. 1B, locked loop circuits 124 and 122 generate the LPCLK signal. In some embodiments, the locked loop circuit 122 is comprised of a phase frequency detector (PFD) 136, a loop filter and voltage-controlled oscillator 135, a phase mixer 140, delay 142, and transmit delay (TxDly) 144. The PFD 136 receives refclk_LC and a delayed signal from the phase mixer 140. The loop filter and voltage-controlled oscillator 135 receives a signal output by the PFD 136 and produces a set of clock phasors that are collectively called pll_clk. While the embodiment in FIG. 1B shows pll_clk as being a set of four clock phasors, in other embodiments pll_clk may have a eight phasors, or yet another number of phasors. The signal, pll_clk, is sometimes called a clock signal, even though it is a set of phasors. The phase mixer 140 receives an adjustment signal from an adjustment circuit or register (e.g., a register storing one or more values established during a calibration operation) FBADJ 138 and the clock signal pll_clk from the loop filter and voltage-controlled oscillator 135. The adjustment signal from FBADJ 138 consists of a programmable value, which can be used to cancel out any potential delay mismatch between the delay T_{FBCLK} (caused by delay 142 and transmit delay TxDly 144), and the delay T_{DLPCLK} (caused by divider 145 and buffer 149, which are discussed below). In some cases (e.g., when T_{FBCLK} is equal to T_{DLPCLK}) the FBADJ value is set to zero. The output of the phase mixer 140 is delayed by delay 142 and TxDly 144 for a time equal to T_{FBCLK} before it is received by the PFD 136. The pll_clk clock signal produced by locked loop circuit 122 is coupled to phase mixer 130 of the locked loop circuit 124 and phase mixer 148.

The locked loop circuit 124 receives pll_clk from the locked loop circuit 122 and receives the aforementioned PCLK signal from an external source. In some embodiments, the locked loop circuit 124 includes a phase detector (PD) 126, an LPCLK control circuit 128, the phase mixer 130, a frequency divider 132 and a delay 134, all connected in series, in a loop as shown in FIG. 1B. In some embodiments, frequency divider 132 is reset by a reset signal (reset) when the controller 100 (FIG. 1A) is powered on. The PD 126 of the locked loop circuit 124 receives PCLK and a feedback LPCLK signal. The output signal of phase mixer 130 is delayed by frequency divider 132 and delay 134 for a time equal to T_{LPCLK} to produce LPCLK. The output of the locked loop circuit 124 is LPCLK.

A phase detector (PD) 146 receives LPCLK and a delayed output signal from phase mixer 148. A counter circuit (LPCNT) 147 counts output signals produced by the PD 146. Phase mixer 148 receives the count value, dlpclk_cnt, produced by LPCNT 147 and pll_clk (i.e., a set of phasors) from the locked loop circuit 122. The clock signal output of phase mixer 148 is divided by frequency divider 145 and delayed by delay 149. Ideally, and often in practice, T_{DLPCLK}, the delay associated with divider 145 and delay 149, is matched to T_{FBCLK}. In some embodiments, frequency divider 145 is reset by a reset signal (reset) when the controller 100 (FIG. 1A) is powered on.

As also shown in FIG. 1B, a bit slice pair 150-n includes a locked loop circuit 152, first and second phase mixers 158 and 176, respectively, a plurality of registers 156 (DCLK0 registers) and 172 (DCLK1 registers), and a plurality of control circuits 162, 164, 166, and 178. An embodiment of control circuits 162, 164 and 178 is discussed below with reference to FIG. 1C.

The locked loop circuit 152 (e.g., a PLL) is coupled to the first and second phase mixers 158 and 176, respectively. As stated above, the locked loop circuit 152 generates pll_clk1 and sclk. In some embodiments, the locked loop circuit 152 includes a phase frequency detector (PFD) 153, a loop filter and voltage-controlled oscillator 155, a phase mixer 168, delay 170, and transmit delay (TxDly) 174. The PFD 153 receives refclk_LC (see FIG. 1A) and a delayed signal from the phase mixer 168. The loop filter and voltage-controlled oscillator 155 receives the output of the PFD 153, which compares the phase of a reference signal, refclk_LC, with the phase of a delayed signal from phase mixer 168. Phase mixer 168 receives a control signal from a control circuit (SCLK CTRL) 166 and the clock signal pll_clk1 produced by the loop filter and voltage-controlled oscillator 155. The control signal from SCLK CTRL 166 consists of programmable bits, which in most cases are set to zero. SCLK CTRL 166 is similar to FBADJ 138 in that the values output by SCLK CTRL 166 are used to cancel out any potential delay mismatch between a first delay, caused by buffer 170 and delay 174, and a second delay caused by delay 160 or 175 and the transmit delay of the first or second bit slice. The output of the phase mixer 168 is delayed by delay 170 and TxDly 174 before it is received by the PFP 153. In some embodiments, TxDly matches a clock-to-output delay in bit slice 154x. For example, TxDly may be equal to the delay of an output multiplexer 234 (FIG. 2A) and an output driver 236 (FIG. 2A).

The output signal of delay 170 is sclk. Frequency divider 177 divides sclk to produce div_sclk (a clock signal having a frequency that is one-eighth (or, more generally, 1/N) of the frequency of sclk) and div_sclk_cnt (a count value indicating the current state of the divider 177). In some embodiments, frequency divider 177 is reset by a reset signal (reset) when the controller 100 (FIG. 1A) is powered on. Although not shown in FIG. 1B, there are four frequency dividers in 177, including two for each bit slice. In each slice, one divider is for TX and the other is for RX. Two of these dividers 202, for one bit slice, are shown in FIG. 2A. Frequency divider 177 also produces four div_sclk_cnt signals (two per bit slice, one for TX and one for RX of each bit slice), because the skip control circuit SKIP CNTRL 164 uses one div_sclk_cnt signal for RX and one for TX in each of the two bit slices.

A control circuit (SKIP CNTRL) 164 receives a digital output signal (dlpclk_cnt) from LPCNT 147 and four digital output signals (each called div_sclk_cnt) from the four frequency dividers 177 (see discussion above concerning the number of dividers 177). SKIP CNTRL 164 generates four skip signals (sskip), each for use in transmit path skip circuit 214 (FIG. 2A) or a receive path skip circuit 244 (FIG. 2A) as described below in relation to FIGS. 2A and 2B. Each respective skip signal (sskip) represents the phase skew (also called the phase difference) between LPCLK and a respective div_sclk. The timing relationship between sskip with respect to LPCLK and div_sclk is described below in FIG. 2C.

In the descriptions below, the suffix <0> merely indicates that the signal is used in the first bit slice 154a (FIG. 1A), and the suffix <1> merely indicates that the signal is used in the second bit slice 154b (FIG. 1A).

The first bit slice 154a (FIG. 1A) includes the first phase mixer 158, DCLK0 Regs 156, and a transition control circuit (TRANSITION CNTRL0) 162. The first phase mixer 158 receives an adjustment signal from DCLK0 Regs 156 and receives pll_clk1 from the locked loop circuit 152. The adjustment signals stored in DCLK0 Regs 156 correspond to adjustment values used in the transmit and receive modes of operation to center the output of first phase mixer 158 optimally for transmission and reception. The adjustment values stored in DCLK0 Regs 156 are obtained during a calibration mode of operation. The output of the first phase mixer 158 is delayed by delay 160. The output of delay 160 is a clock signal dclk<0>, which is used in the first bit slice 154a (FIG. 1A) as described below in relation to FIG. 2A.

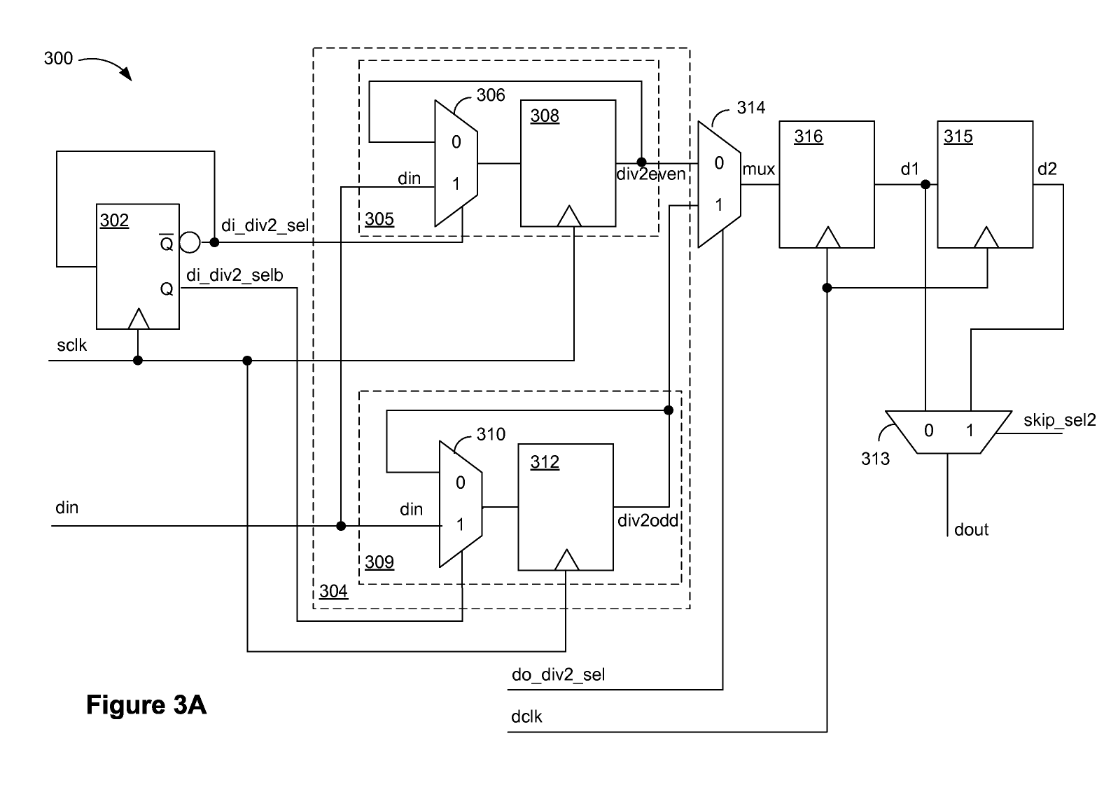

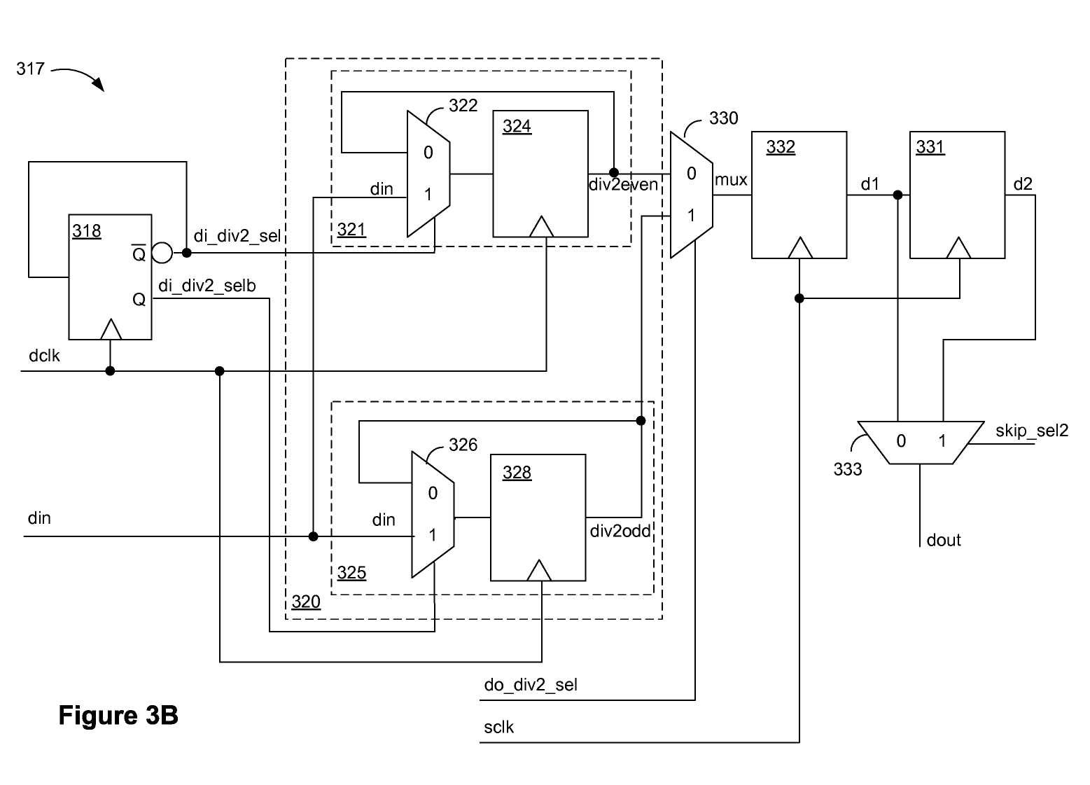

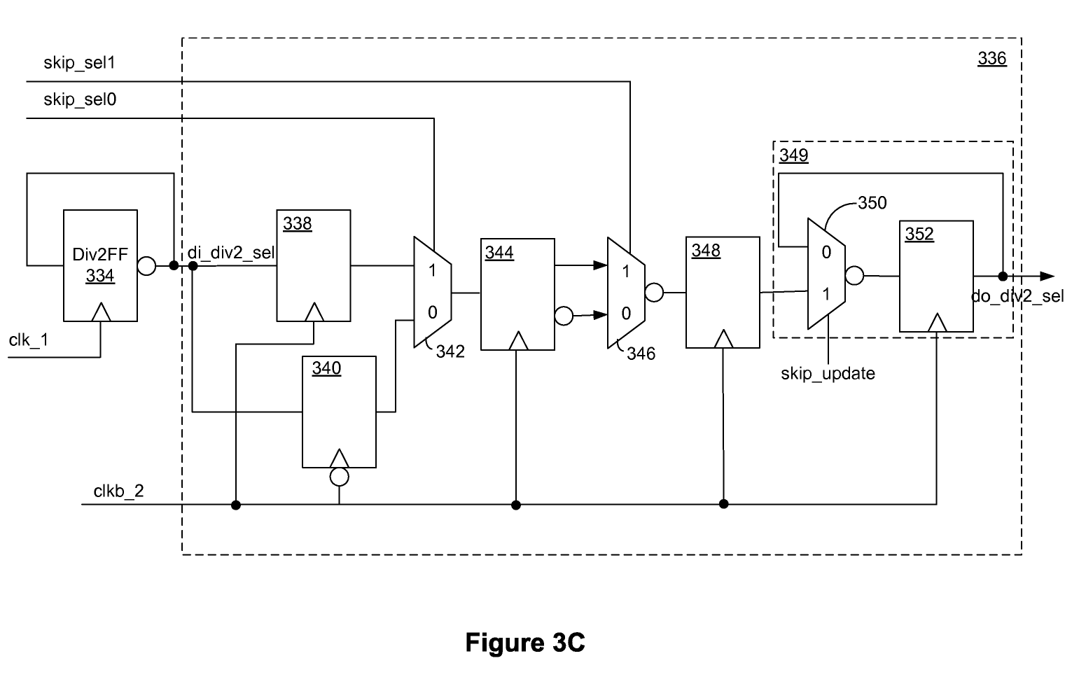

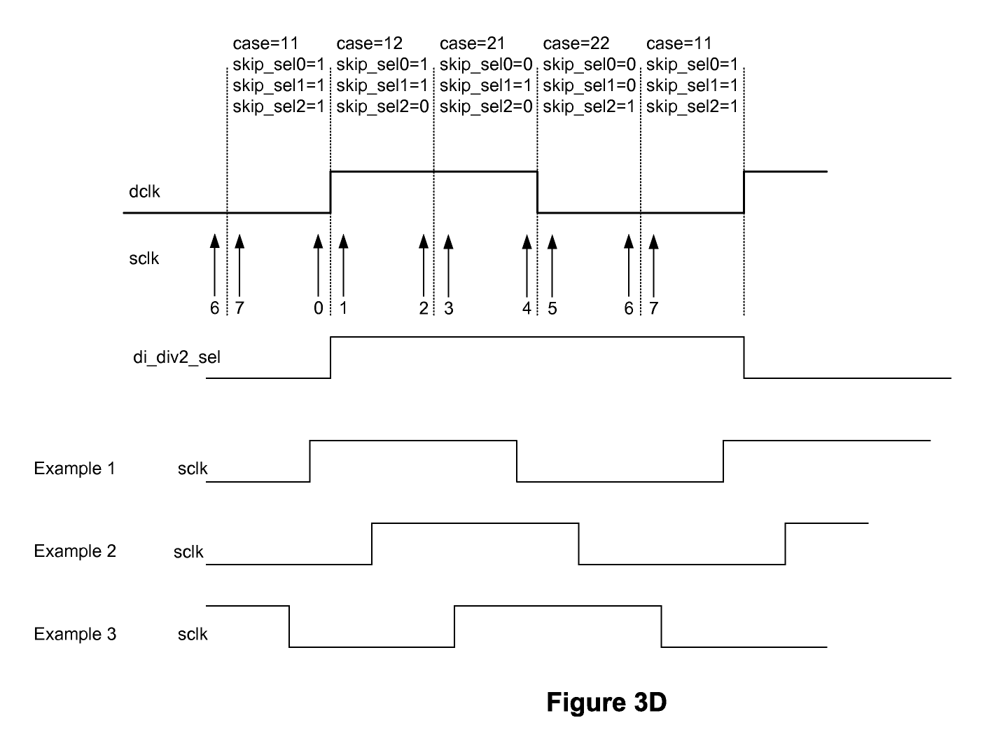

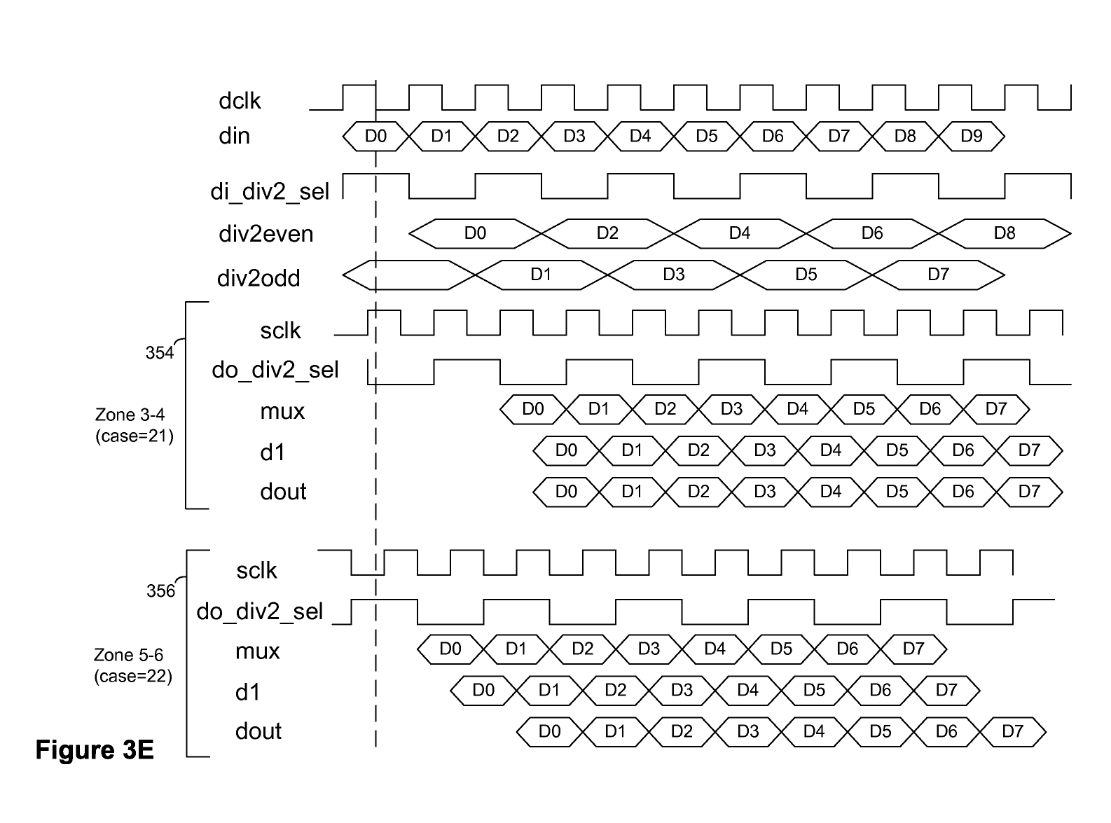

TRANSITION CNTRL0 162 receives two adjustment signals from DCLK0 Regs 156 (one for the transmission path and one for the receive path of the first bit slice) and an output from SCLK CTRL 166, and generates two sets of skip control signals (skip_sel<0> and skip_update<0>). In some embodiments, each skip_sel<0> includes three skip control signals (skip_sel0, skip_sel1, and skip_sel2). The synthesis of skip_sel0, skip_sel1, and skip_sel2 is described below in relation to FIG. 3D. To determine the values of the skip_sel<0> signals, TRANSITION CNTRL0 162 compares the adjustment signals (one for the transmit path and one for the receive path of the first bit slice) from DCLK0 Regs 156 and the output from SCLK CTRL 166. Because the output from SCLK CTRL 166 is zero in most cases, the values of the adjustment signals from DCLK0 Regs 156 represent the phase difference between dclk and div_sclk in the transmit and receive paths of the first bit slice. The skip_sel<0> signals for the transmit and receive paths are based on these phase differences, as described below and as shown in FIG. 3D. In addition, TRANSITION CNTRL0 162 includes two change-in-value detectors that detects any change in value of the difference between the DCLK0 register values and the SCLK CTRL value. For example, this value typically changes whenever the first bit slice changes from a read mode to a write mode, or vice versa, because the DCLK0 values are typically different for read mode and write mode. When TRANSITION CNTRL0 162 detects a change in value of the difference between the DCLK0 register value and the SCLK CTRL value, the corresponding skip_update<0> signal is briefly enabled for a few clock cycles, e.g., three clock cycles of the dclk or sclk signal. The use of skip_sel0, skip_sel1, and skip_update<0> is described below in relation to FIG. 3C and the use of skip_sel2 is described below in relation to FIGS. 3A and 3B. The timing relationship of skip_sel0, skip_sel1, and skip_sel2 with respect to dclk and sclk is described below in relation to FIG. 3D.

The second bit slice 154b (FIG. 1A) includes the second phase mixer 176, DCLK1 Regs 172, and a transition control circuit (TRANSITION CNTRL1) 178. The second phase mixer 176 receives an adjustment signal from DCLK1 Regs 172 and receives pll_clk1 from the locked loop circuit 152. The adjustment signals stored in DCLK1 Regs 172 correspond to adjustment values used in the transmit and receive modes of operation to center the output of second phase mixer 176 optimally for transmission and reception. The adjustment values in DCLK1 Regs 172 are obtained during a calibration mode of operation. The output of the second phase mixer 176 is delayed by delay 175 to produce clock signal dclk<1>, which is used in the second bit slice 154b (FIG. 1A) as described below in relation to FIG. 2A.

FIG. 1C shows one embodiment of the TRANSITION CNTRL0 162, TRANSITION CNTRL1 178 and SKIP CNTRL 164 control circuits. In this embodiment, subtraction circuits 180, 184 are used to produce a phase difference value indicative of a “region of operation” in terms of the phase difference between two clock signals or two clock domains. Decoder circuits 181, 185 are then used to decode the phase difference value into skip control signals. TRANSITION CNTRL0 162, for the first bit slice, includes a subtraction circuit 180-0-T for subtracting a SCLK_CTRL value from a transmit path value obtained from the DCLK0 Regs 156, or vice versa. The resulting value is decoded by decoder 180-0-T in accordance with the phase difference regions shown in FIG. 3D to produce three skip selection signals, skip_sel0, skip_sel1 and skip_sel2, collectively called skip_sel<0, Tx> for the transmit path of the first bit slice. A change in value detector 182-0-T outputs a pulse signal, called skip_update<0, Tx> whenever the value output by the subtraction circuit 180-0-T changes in value. Subtraction circuit 180-0-T, decoder 181-0-T and change in value detector 182-0-T form a first subcircuit of TRANSITION CNTRL0 162. A second subcircuit of TRANSITION CNTRL0 162 includes a subtraction circuit 180-0-R, decoder 181-0-R and change in value detector 182-0-R to produce a corresponding set of skip control signals (skip_sel<0, Rx>, skip_update<0, Rx>) for the receive path of the first bit slice based on a receive path value obtained from the DCLK0 Regs 156.

FIG. 1C shows that TRANSITION CNTRL1 178 contains two subcircuits that are substantially similar to the two subcircuits of TRANSITION CNTRL0 162. A first one of the subcircuits produces skip control signals (skip_sel<1, Tx>, skip_update<1, Tx>) for a transmit path of the second bit slice, and a second one of the subcircuits produces skip control signals (skip_sel<1, Rx>, skip_update<1, Rx>) for a receive path of the second bit slice.

FIG. 1C also shows that SKIP CNTRL 164 includes four subcircuits, each having a subtraction circuit 184 (184-0-T, 184-0-R, 184-1-T, 184-1-R) and a decoder 185 (185-0-T, 185-0-R, 185-1-R, 185-1-R). Each subtraction circuit 184 subtracts a respective div_sclk_cnt value from dlpclk_cnt, or vice versa, to produce a phase difference value (e.g., a value corresponding to case 0 or case 1 in FIG. 2C), which is then decoded by the corresponding decoder 185 to produce a respective sskip control signal, sskip(0-Tx), sskip(0-Rx), sskip(1-Tx), or sskip(1-Rx). The decoders 185 operate in accordance with the phase difference value to skip control signal mapping shown in FIG. 2C.

TRANSITION CNTRL1 178 receives two adjustment signals from DCLK1 Regs 172 (one for the transmission path and one for the receive path of the second bit slice) and an output from SCLK CNTRL 166, and generates two sets of skip control signals (skip_sel<1> and skip_update<1>). In some embodiments, each skip_sel<1> includes three skip control signals (skip_sel0, skip_sel1, and skip_sel2). The synthesis of skip_sel0, skip_sel1, and skip_sel2 is described below in relation to FIG. 3D. To determine the values of the skip_sel<1> signals, TRANSITION CNTRL1 178 compares the adjustment signals (one for the transmit path and one for the receive path of the second bit slice) from DCLK1 Regs 172 and the output from SCLK CNTRL 166. Because the output from SCLK CNTRL 166 is zero in most cases, the values of the adjustment signals from DCLK1 Regs 172 represent the phase difference between dclk and div_sclk in the transmit and receive paths of the second bit slice. The skip_sel<1> signals for the transmit and receive paths are based on these phase differences, as described below and as shown in FIG. 3D. In addition, TRANSITION CNTRL1 178 includes two change-in-value detectors that detect any change in value of the difference between the DCLK1 register values and the SCLK CTRL value. For example, this value typically changes whenever the second bit slice changes from a read mode to a write mode, or vice versa, because the DCLK1 values are typically different for read mode and write mode. When TRANSITION CNTRL1 178 detects a change in value of the difference between the DCLK1 register value and the SCLK CTRL value, the corresponding skip_update<1> signal is briefly enabled for a few clock cycles, e.g., three clock cycles of the dclk or sclk signal. The use of skip_sel0, skip_sel1, and skip_update<1> is described below in relation to FIG. 3C and the use of skip_sel2 is described below in relation to FIGS. 3A and 3B. The timing relationship of skip_sel0, skip_sel1, and skip_sel2 with respect to dclk and sclk is described below in relation to FIG. 3D.

FIG. 2A illustrates the bit slice circuit 154x in accordance with some embodiments. The bit slice circuit 154x is a bidirectional device. Accordingly, the bit slice circuit 154x writes transmit data (e.g., tdata) to and reads receive data (e.g., rdata) from a corresponding memory circuit 190-x. Memory 190-x is any one of the plurality of memory circuits 190-1, 190-2, . . . 190-n. The bit slice circuit 154x couples to memory circuit 190-x at a transmit memory interface 268 and a receive memory interface 270. As the bit slice circuit 154x progresses from a transmit/write mode to a receive/read mode, a bus turnaround procedure is performed at a point in the middle of the transmit memory interface 268 and the receive memory interface 270.

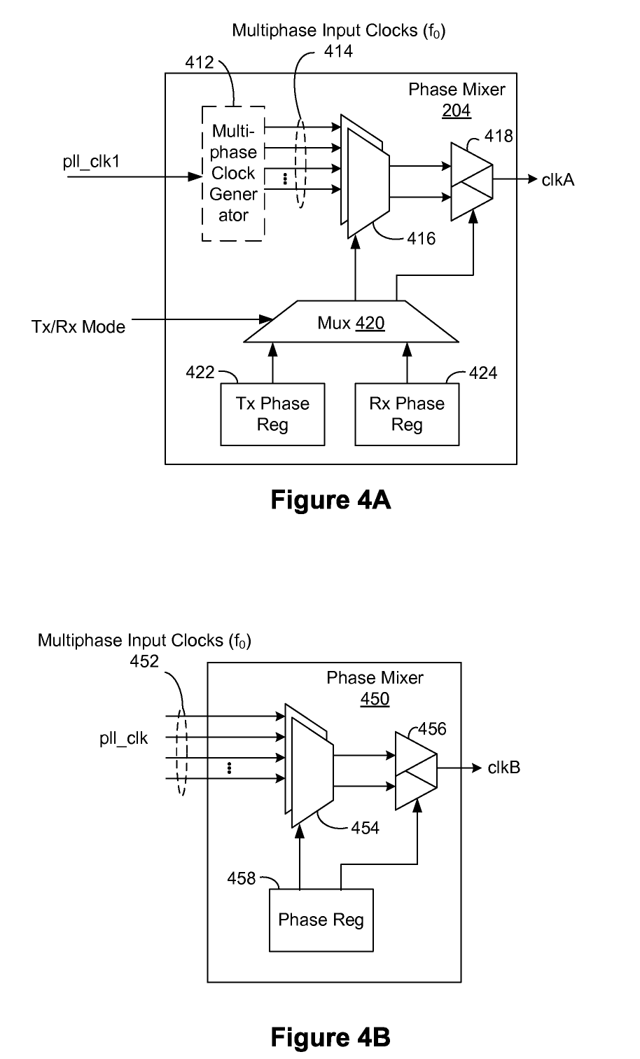

As shown in FIG. 2A, the bit slice circuit 154x receives three different clock signals, LPCLK, sclk and pll_clk1, and includes a phase mixer 204. Phase mixer 204 corresponds to either one of phase mixer 158 (FIG. 1B) or phase mixer 176 (FIG. 1B), as well as the associated delays 160 or 175. Phase mixer 204, which is discussed in detail below in relation to FIG. 4A, receives the pll_clk1 signal from the locked loop circuit 152 (FIG. 1B), and outputs a clock signal dclk for use by the bit slice circuit 154x. In some embodiments, dclk has a frequency of 8 GHz. The phase mixer 204 outputs dclk with a first phase (sometimes represented digitally by a first phase code) for the transmit/write mode and a second phase (sometimes represented digitally by a second phase code) for the receive/read mode. During bus turnaround the phase code for dclk is updated to the corresponding direction.

It is noted that each bit slice circuit 154x operates in three clock domains: the clock domain of LPCLK, the clock domain of sclk, and the clock domain of dclk. As described below, skip circuits 214, 244 provide smooth data transitions between the LPCLK and sclk clock domains, and transmit transition 220 and receive transition 250 circuits provide smooth data transitions between the sclk and dclk claim domains.

The transmit data is transmitted through a transmit data path that begins at an input of a first transmit circuitry 210 and ends at a transmit memory interface 268. The transmit data path includes a first transmit circuitry 210, a transmit transition circuitry 220, and a second transmit circuitry 230. The transmit transition circuitry 220 couples the first transmit circuitry 210 to the second transmit circuitry 230. In some embodiments, the transmit data path has an average length of not more than three clock cycles of dclk.

The first transmit circuitry 210 receives LPCLK and sclk. The first transmit circuitry 210 includes a levelization circuit 212, a skip circuit 214 and a serializer circuit 216, connected in series. The levelization circuit 212 receives LPCLK and the transmit data. The levelization circuit 212 manages the flow of data to memory circuit 190-x. The skip circuit 214 ensures that the data in the levelization circuit 212 is properly handed off to the serializer circuit 216. The levelization circuit 212 and the serializer circuit 216 operate in different clock domains. The skip circuit 214 receives sskip, which represents the phase skew between two input clocks, from SKIP CNTRL 164 (FIG. 1B). In some embodiments, the two input clocks are LPCLK and the divided sclk signal, div_sclk, output by divider 202 (177 in FIG. 1B). In some embodiments, the skip circuit 214 is the skip circuit 280 (FIG. 2B) described below in relation to FIG. 2B. In other embodiments, the skip circuit 214 is similar to the fast skip circuit 300 (FIG. 3A) of the transmit transition circuitry 220 described below. The serializer circuit 216 receives sclk as well as the divided sclk, div_sclk.

The transmit transition circuitry 220 ensures that the data in the clock domain of sclk is properly handed off to the clock domain of dclk. Because data must be passed between two different high-speed (e.g., 8 GHz) clock domains (e.g., the clock domains of sclk and dclk) that have an unknown phase relationship with each other, specialized transmit transition circuitry 220 is needed to avoid incurring bit errors. The skip margin of the transmit transition circuitry 220 is the maximum timing uncertainty that the transmit transition circuitry can allow between the two clock domains before incurring bit errors. In some embodiments, the skip margin of the transmit transition circuitry is half of a clock cycle of dclk. In some embodiments, the transmit transition circuitry 220 includes a fast skip circuit 300 (FIG. 3A) that generates the output signals. The two input clocks of the transmit transition circuitry 220 are sclk and dclk. The transmit transition circuitry 220 is discussed in detail below in relation to FIGS. 3A-E. Specifically, a fast skip circuit 300 (FIG. 3A) of the transmit transition circuitry 220 is discussed below in relation to FIG. 3A, and a configuration circuit 336 (FIG. 3C) for the fast skip circuit 300 (FIG. 3A) of the transmit transition circuitry 220 is discussed below in relation to FIG. 3C.

The second transmit circuitry 230 receives dclk and operates in a second clock domain (i.e., the clock domain of dclk). The second transmit circuitry 230 includes an even/odd aligner 232, and an output multiplexer or predriver 234, and an output driver 236. In some embodiments, the second transmit circuitry 230 includes the transmit memory interface 268.

The receive data is received through a receive data path that begins at a receive memory interface 270 and ends at an output of a first receive circuitry 240. The receive data path includes a second receive circuitry 260, a receive transition circuitry 250, and a first receive circuitry 240. The receive transition circuitry 250 couples the first receive circuitry 240 to a second receive circuitry 260. In some embodiments, the receive data path has an average length of not more than three clock cycles of dclk.

The second receive circuitry 260 receives dclk and operates in the second clock domain. The second receive circuitry 260 includes an even/odd aligner 262, a receive DFE/Samp 264, and a receive Preamp or Linear EQ 266. In some embodiments, the second receive circuitry 260 includes the receive memory interface 270.

The receive transition circuitry 250 ensures that the receive data in the clock domain of dclk is properly handed off to the clock domain of sclk. As stated above with respect to the transmit transition circuitry 220, because data must be passed between two different high-speed (e.g., 8 GHz) clock domains (e.g., the clock domains of sclk and dclk) that have an unknown phase relationship with each other, specialized receive transition circuitry 250 is needed to avoid incurring bit errors. Again, the amount of timing uncertainty that the receive transition circuitry 250 can allow between the two clock domains before incurring bit errors is called the skip margin. In some embodiments, the skip margin of the receive transition circuitry 250 is half of a clock cycle of dclk. In some embodiments, the receive transition circuitry 250 includes a fast skip circuit 317 (FIG. 3B) that generates the output signals. The two input clocks of the receive transition circuitry 250 are sclk and dclk. The receive transition circuitry 250 is discussed in detail below in relation to FIGS. 3A-E. Specifically, the fast skip circuit 317 (FIG. 3B) of the receive transition circuitry 250 is discussed below in relation to FIG. 3B and a configuration circuit 336 (FIG. 3C) for fast skip circuit 317 (FIG. 3B) of the receive transition circuitry 250 is discussed below in relation to FIG. 3C.

The first receive circuitry 240 receives LPCLK and sclk. The first receive circuitry 240 includes a levelization circuit 242, a skip circuit 244, and a deserializer circuit 246. The levelization circuit 242 receives LPCLK and outputs the receive data. The levelization circuit 242 manages the flow of data from memory circuit 190-x. The skip circuit 244 ensures that the data in the deserializer circuit 246 is properly handed off to the levelization circuit 242. The deserializer circuit 246 and the levelization circuit 242 operate in different clock domains. The skip circuit 244 receives sskip, which represents the phase skew between two input clocks, from SKIP CNTRL 164 (FIG. 1B). In some embodiments, the two input clocks are LPCLK and div_sclk. In some embodiments, the skip circuit 244 is the skip circuit 280 (FIG. 2B) described below in relation to FIG. 2B. In other embodiments, the skip circuit 244 is similar to the fast skip circuit 317 (FIG. 3B) of the receive transition circuitry 250 described above. The deserializer circuit 246 receives sclk and also receives the divided sclk produced by frequency divider 203.

FIG. 2B is a block diagram illustrating a skip circuit 280 in accordance with some embodiments. The skip circuit 280 includes a first memory element 272, a second memory element 274, a multiplexer 276, and a third memory element 278. The multiplexer 276 logically couples first memory element 272 and second memory element 274 to third memory element 278. First memory element 272 receives a data input signal (din) and is triggered by LPCLK. Second memory element 274 receives din and is triggered by the inverse of LPCLK. In some embodiments, first and second memory elements 272 and 274, respectively, are flip flops. Multiplexer 276 receives the outputs of first and second memory elements 272 and 274, respectively, and selects between the two inputs based on sskip. The synthesis of sskip is described above in reference to FIG. 1B and below in reference to FIG. 2C. Third memory element 278 receives the output of multiplexer 276 and is triggered by div_sclk. Third memory element 278 outputs a data output signal (dout). In some embodiments, third memory element 278 is a flip flop. The timing relationship for clock signals used in skip circuit 280 are discussed below in relation to FIG. 2C.

FIG. 2C illustrates an exemplary timing relationship of the signals in the skip circuit 280 of FIG. 2B in accordance with some embodiments. As shown in FIG. 2C, the value of sskip follows two different cases: case 0; and case 1. In case 0, sskip is equal to zero. In case 1, sskip is equal to one. Further, LPCLK is broken into two zones with respect to one clock cycle: 1-2; and 3-4. The zone in which div_sclk rises with respect to LPCLK determines which case is used. SKIP CNTRL 164 (FIG. 1B) subtracts div_sclk_cnt from dlpclk_cnt to determine the phase skew between LPCLK and div_sclk, and thus, which zone div_sclk rises with respect to LPCLK. Accordingly, if SKIP CNTRL 164 (FIG. 1B) determines that div_sclk rises in zone 1-2, case 0 is selected and sskip is equal to 0. If SKIP CNTRL 164 (FIG. 1B) determines that div_sclk rises in zone 3-4, case 1 is selected and sskip is equal to 1.

FIG. 3A is a block diagram illustrating the fast skip circuit 300 of the transmit transition circuitry 220 (FIG. 2A) in accordance with some embodiments. The skip circuit 300 includes a clock divider circuit 302, a first memory element 304, a first multiplexer 314, a second memory element 316, a third memory element 315, and a second multiplexer 313. The first multiplexer 314 logically couples first memory element 304 to second memory element 316. The timing relationship for clock signals used in the fast skip circuit 300 are discussed below in relation to FIG. 3E.

The clock divider circuit 302 divides sclk into two signals, di_div2_sel and di_div2_selb, each with a frequency that is half of the frequency of sclk. In some embodiments, the frequency of di_div2_sel and di_div2_selb is 4 GHz. In some embodiments, the clock divider circuit 302 is a flip flop.

First memory element 304 includes a first data selection circuit 305 and a second data selection circuit 309.

The first data selection circuit 305 includes a multiplexer 306, and a memory element 308. Multiplexer 306 receives two signal inputs, din and a feedback signal of the output for the memory element 308, and a selector input, di_div2_sel. Memory element 308 receives the output of the multiplexer 306 and is triggered by sclk. In some embodiments, memory element 308 is triggered by a clock signal that is synchronous with sclk. In some embodiments, memory element 308 is a flip flop. Memory element 308 outputs the even bits of din (div2even). The frequency of the div2even is equal to the frequency of di_div2_sel. In some embodiments, the frequency of div2even is 4 GHz.

The second data selection circuit 309 includes a multiplexer 310, and a memory element 312. Multiplexer 310 receives two signal inputs, din and a feedback signal of the output for the memory element 312, and a selector input, di_div2_selb. Memory element 312 receives the output of the multiplexer 310 and is triggered by sclk. In some embodiments, memory element 312 is triggered by a clock signal that is synchronous with sclk. In some embodiments, memory element 312 is a flip flop. Memory element 312 outputs the odd bits of din (div2odd). The frequency of the div2odd is equal to the frequency of di_div2_selb. In some embodiments, the frequency of div2odd is 4 GHz.

The first multiplexer 314 receives div2even and div2odd, and selects between the two inputs based on a configuration clock signal (do_div2_sel). The synthesis of do_div2_sel is described below in reference to FIG. 3C. The first multiplexer 314 outputs a signal (mux) that has a frequency equal to the frequency of sclk. In some embodiments, the frequency of mux is 8 GHz.

The second memory element 316 receives mux from the first multiplexer 314 and outputs a data output signal (d1) to the third memory element 315 and the second multiplexer 313. In some embodiments, the second memory element 316 is a flip flop that is clocked by dclk.

The third memory element 315 receives d1 from the second memory element 316 and outputs a data output signal (d2) to the second multiplexer 313. In some embodiments, the third memory element 315 is a flip flop that is clocked by dclk.

The second multiplexer 313 selects between inputs d1 and d2 based on a configuration clock signal (skip_sel2) and outputs a data output signal (dout). The synthesis of skip_sel2 is described above in relation to FIG. 1B and the timing relationship of skip_sel2 with respect to dclk, sclk, and di_div2_sel is described below in relation to FIG. 3D. Output signal dout, which is received by second transmit circuitry 230 (see FIG. 2A), has a frequency equal to the frequency of dclk (which is also the frequency of sclk). In some embodiments, the frequency of dout is 8 GHz. The timing relationship of skip_sel2 with respect to sclk and dclk is described below in reference to FIG. 3D.

FIG. 3B is a block diagram illustrating the fast skip circuit 317 of the receive transition circuitry 250 (FIG. 2A) in accordance with some embodiments. The skip circuit 317 includes a clock divider circuit 318, a first memory element 320, a first multiplexer 330, a second memory element 332, a third memory element 331, and a second multiplexer 333. The first multiplexer 330 logically couples first memory element 320 to second memory element 332. The timing relationship for clock signals used in the fast skip circuit 317 are discussed below in relation to FIG. 3E.

The clock divider circuit 318, divides dclk into two signals, di_div2_sel and di_div2_selb, each with a frequency that is half of the frequency of dclk. In some embodiments, the frequency of di_div2_sel and di_div2_selb is 4 GHz. In some embodiments, the clock divider circuit 318 is a flip flop.

First memory element 320 includes a first data selection circuit 321 and a second data selection circuit 325.

The first data selection circuit 321 includes a multiplexer 322, and a memory element 324. Multiplexer 322 receives two signal inputs, din and a feedback signal of the output for the memory element 324, and a selector input, di_div2_sel. Memory element 324 receives the output of the multiplexer 322 and is triggered by dclk. In some embodiments, memory element 324 is triggered by a clock signal that is synchronous with dclk. In some embodiments, memory element 324 is a flip flop. Memory element 324 outputs the even bits of din (div2even). The frequency of the div2even is equal to the frequency of di_div2_sel. In some embodiments, the frequency of div2even is 4 GHz.

The second data selection circuit 325 includes a multiplexer 326, and a memory element 328. Multiplexer 326 receives two signal inputs, din and a feedback signal of the output for the memory element 328, and a selector input, di_div2_selb. Memory element 328 receives the output of the multiplexer 326 and is triggered by dclk. In some embodiments, memory element 328 is triggered by a clock signal that is synchronous with dclk. In some embodiments, memory element 328 is a flip flop. Memory element 328 outputs the odd bits of din (div2odd). The frequency of the div2odd is equal to the frequency of di_div2_selb. In some embodiments, the frequency of div2odd is 4 GHz.

The first multiplexer 330 receives div2even and div2odd, and selects between the two inputs based on do_div2_sel. As stated above, the synthesis of do_div2_sel is described below in reference to FIG. 3C. The first multiplexer 330 outputs a signal (mux) that has a frequency equal to the frequency of dclk. In some embodiments, the frequency of mux is 8 GHz.

The second memory element 332 receives mux from the first multiplexer 330 and outputs data output signal (d1) to the third memory element 331 and the second multiplexer 333. In some embodiments, the second memory element 332 is a flip flop that is clocked by sclk.

The third memory element 330 receives d1 from the second memory element 332 and outputs a data output signal (d2) to the second multiplexer 333. In some embodiments, the third memory element 331 is a flip flop that is clocked by sclk.

The second multiplexer 333 selects between inputs d1 and d2 based on a configuration clock signal (skip_sel2) and outputs a data output signal (dout). The synthesis of skip_sel2 is described above in relation to FIG. 1B and the timing relationship of skip_sel2 with respect to dclk, sclk, and di_div2_sel is described below in relation to FIG. 3D. Output signal dout, which is received by first receive circuitry 240 (see FIG. 2A), has a frequency equal to the frequency of sclk (which is also the frequency of dclk). In some embodiments, the frequency of dout is 8 GHz. The timing relationship of skip_sel2 with respect to sclk and dclk is described below in reference to FIG. 3D.

FIG. 3C is a block diagram illustrating a configuration circuit 336 for the transmit transition circuitry 220 (FIG. 2A) and receive transition circuitry 250 (FIG. 2A) in accordance with some embodiments. The configuration circuit 336 determines the phase of do_div2_sel, based on the phase relationship between dclk, sclk and skip control signals, skip_sel0 and skip_sel1.

Please note that in the description below, clk_1 is sclk, clk_2 is dclk, and clkb_2 is dclkb for the transmit transition circuitry 220 (FIG. 2A), while for the receive transition circuitry 250 (FIG. 2B) clk_1 is dclk, clk_2 is sclk, and clkb_2 is sclkb (which is the inverse of sclk).

The configuration circuit 336 is coupled to a clock divider circuit 334. The clock divider circuit 334, divides clk_1 into two signals, di_div2_sel and di_div2_selb (not shown), each with a frequency that is half of the frequency of clk_1. In some embodiments, the frequency of di_div2_sel and di_div2_selb is 4 GHz. In some embodiments, the clock divider circuit 334 is a flip flop.

The configuration circuit 336 includes a plurality of memory elements 338, 340, 344, and 348, a plurality of multiplexers 342, and 346, and a skip update circuit 349. In some embodiments, memory elements 338, 340, 344, and 348 are flip flops. Memory elements 338 and 340 receive di_div2_sel and are triggered by clkb_2.

Multiplexer 342 receives the outputs of memory elements 338 and 340 and outputs a signal in accordance with skip_sel0. The value of skip_sel0 is independent of clock glitches. The synthesis of skip_sel0 is described above in relation to FIG. 1B and the timing relationship of skip_sel0 with respect to clk_1 (which is sclk for the transmit transition circuitry, and dclk for the receive transition circuitry), clk_2 (which is dclk for the transmit transition circuitry, and sclk for the receive transition circuitry), and di_div2_sel is described below in relation to FIG. 3D. Memory element 344 receives the output signal of multiplexer 342 and is triggered by clkb_2. In some embodiments, memory element 344 is a flip flop.

Multiplexer 346 receives the output and inverse output of memory element 344 and outputs a signal in accordance with skip_sel1. The synthesis of skip_sel1 is described above in relation to FIG. 1B and the timing relationship of skip_sel1 with respect to clk_1, clk_2, and di_div2_sel is described below in relation to FIG. 3D. Memory element 348 receives the inverse of the output signal of multiplexer 346 and is triggered by clkb_2. In some embodiments, memory element 348 is a flip flop.

The skip update circuit 349 includes a multiplexer 350 and memory circuit 352. Multiplexer 350 receives the output of memory element 348 and a feedback signal of do_div2_sel from memory element 352. Multiplexer 350 outputs a signal in accordance with skip_update. Memory element 352 receives the inverse of the output signal of multiplexer 350 and is triggered by clkb_2. In some embodiments, memory circuit 352 is a flip flop. The output of the skip update circuit 349 is do_div2_sel. When skip_update is equal to one, do_div2_sel is equal to the output of memory element 348. When skip_update is equal to zero, the skip update circuit 349 is “free-running” and do_div2_sel will not change in value despite a change in the output of memory element 348. There is no phase requirement of skip_update.

FIG. 3D illustrates an exemplary timing relationship of the signals in the fast skip circuit 300 of FIG. 3A, the fast skip circuit 317 of FIG. 3B, and the configuration circuit 336 of FIG. 3C in accordance with some embodiments. More specifically, FIG. 3D shows the timing relationships for the transmit transition circuitry, in which case sclk corresponds to clk_1 in FIG. 3C and dclk corresponds to clk_2 in FIG. 3C. However, for the receive transition circuitry (in which clk_1 is dclk and clk_2 is sclk in FIG. 3C), the roles of sclk and dclk in FIG. 3D are reversed, in which case all sclk waveforms in FIG. 3D become dclk waveforms, and all dclk waveforms in FIG. 3D become sclk waveforms. For ease of explanation, the timing relationships in FIG. 3D are explained below only for the transmit transition circuitry; the corresponding timing relationships for the receive transition circuitry are obtained simply by reversing the roles of sclk and dclk.

As shown in FIG. 3D, di_div2_sel has a clock cycle twice as long as dclk. Also as shown in FIG. 3D, the values of skip_sel0, skip_sel1, and skip_sel2 follow four different cases: case 11; case 12; case 21; and case 22. In case 11, skip_sel0, skip_sel1, and skip_sel2 are all equal to one. In case 12, both skip_sel0 and skip_sel1 are equal to one and skip_sel2 is equal to zero. In case 21, both skip_sel0 and skip_sel2 are equal to zero and skip_sel1 is equal to one. In case 22, skip_sel0, skip_sel1, and skip_sel2 are all equal to zero.

Further, dclk is broken into four zones with respect to one clock cycle: 7-0; 1-2; 3-4; and 5-6. The zone in which sclk rises with respect to dclk determines which case is used. If the rising edge of sclk (and the falling edge of sclkb) is located in zone 7-0 (Example 1), case 11 is selected. If the rising edge of sclk is located in zone 1-2 (Example 2), case 12 is selected. If the rising edge of sclk is located in zone 3-4 (Example 3), case 21 is selected. If the rising edge of sclk is located in zone 5-6, case 22 is selected.

FIG. 3E illustrates an exemplary timing relationship of the signals in the transmit transition 220 (FIG. 2A) of FIG. 3A in accordance with some embodiments. The timing relationship of the signals in the receive transition circuitry 250 (FIG. 2A) of FIG. 3B in accordance with some embodiments. Recall that dclk is divided into di_div2_sel and di_div2_selb (not shown) and din is divided into div2even and div2odd. When the rising edge of sclk is located in zone 3-4 (as described in relation to FIG. 3D), the timing relationship between do_div2_sel, mux, d1 and dout is shown by the first set of signals 354. When the rising edge of sclk is located in zone 5-6 (as described in relation to FIG. 3D), the timing relationship between do_div2_sel, mux, d1 and dout is shown by the second set of signals 356. Note that in the second set of signals 356, dout is delayed by one clock cycle with respect to d1.

FIG. 4A is a block diagram illustrating the phase mixer 204 in accordance with some embodiments. The phase mixer 204 receives pll_clk1 from the locked loop circuit 152 (FIGS. 1A-B). In some embodiments, a multi-phase clock generator 412 generates multiphase input clocks 414 from pll_clk1. A selective coupler, such as multiplexer 416, may couple a respective pair of multiphase input clocks 414 to a mixer 418 in accordance with a phase value or command from multiplexer 420. Multiplexer 420 outputs the command in accordance with a transmit or receive mode control signal. Transmit phase register 422 stores the phase value or command signal for the transmit mode. Receive phase register 424 stores the phase value or command signal for the receive mode. The mixer 418 generates a clock signal clkA, such as dclk (FIG. 2A). In some embodiments, the mixer 418 may generate a secondary clock signal by interpolating between the respective pair of multiphase input clocks 452 (FIG. 4B) in accordance with the phase value or command from the multiplexer 420. In some embodiments, therefore, the secondary clock signal may correspond to one or more of the multiphase input clocks 452.

FIG. 4B is a block diagram illustrating a phase mixer 450 in accordance with some embodiments, such as one of the phase mixers 130, 140, 148, or 168 (FIG. 1B). The phase mixer 450 may receive primary clock signals, such as a set of multiphase input clocks 452, from the locked loop circuit 122 or 152 (FIG. 1B). A selective coupler, such as multiplexer 454, may couple a respective pair of multiphase input clocks 452 to a mixer 456 in accordance with a phase value or command signal from phase register 458. The mixer 456 generates a clock signal clkB, such as sclk (FIG. 1B). In some embodiments, the mixer 450 may generate a secondary clock signal by interpolating between the respective pair of multiphase input clocks 452 in accordance with the phase value or command from the phase register 458. In some embodiments, therefore, the secondary clock signal may correspond to one or more of the multiphase input clocks 452.

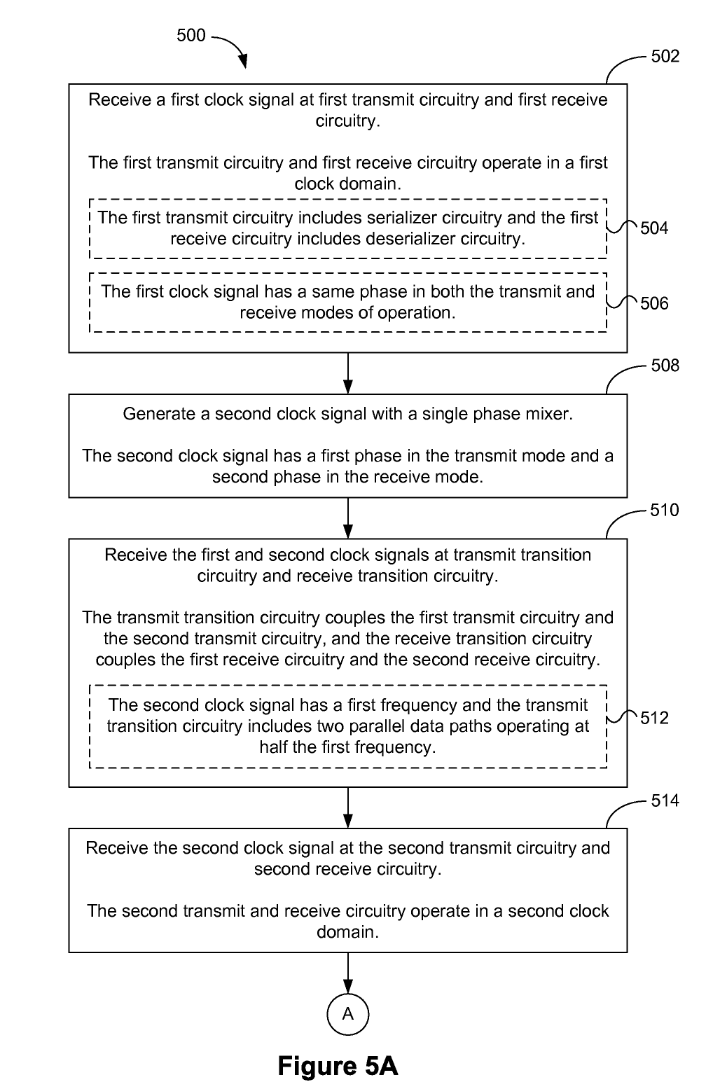

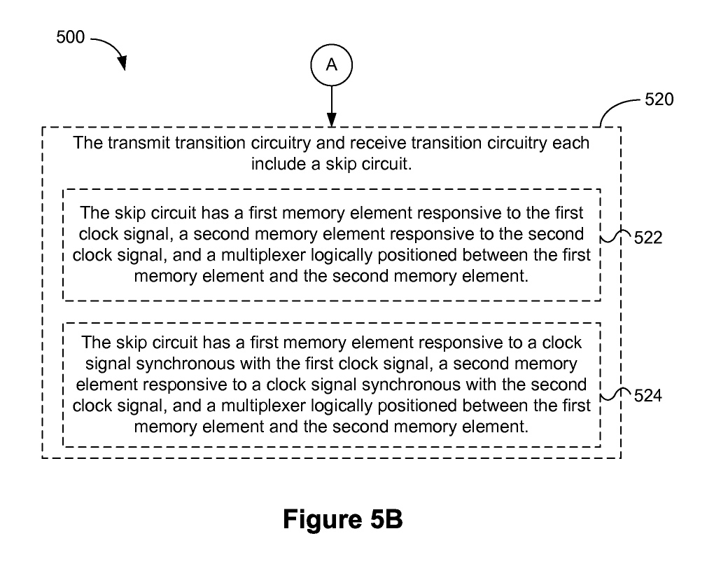

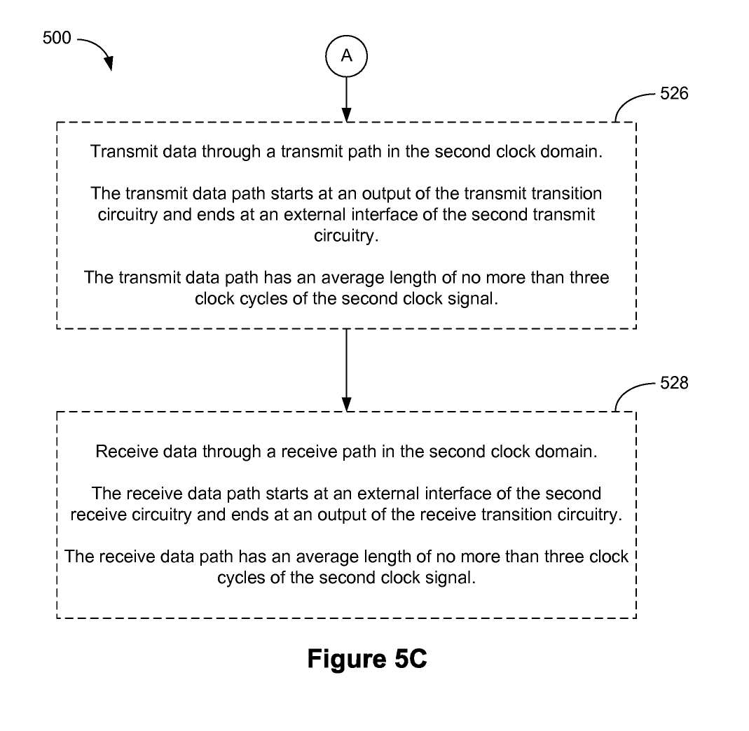

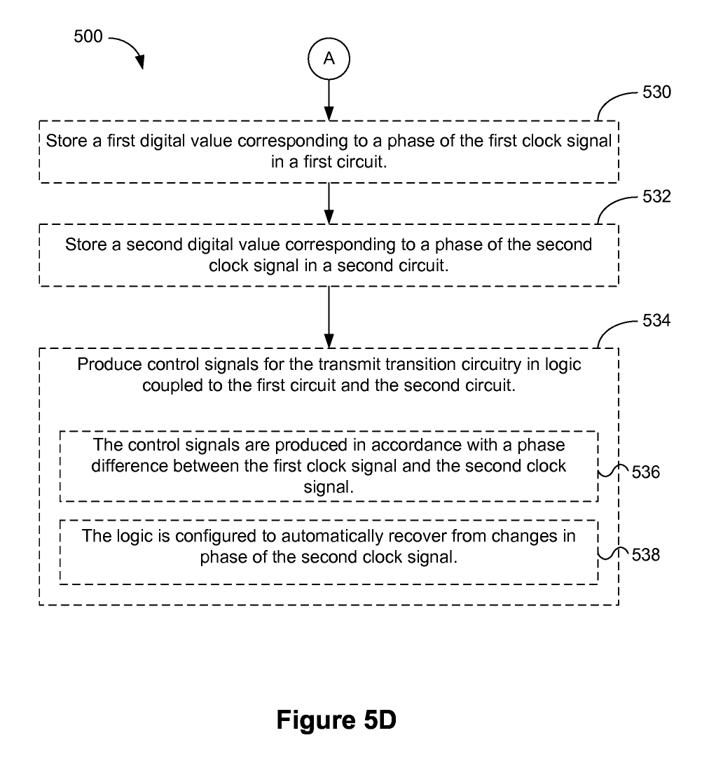

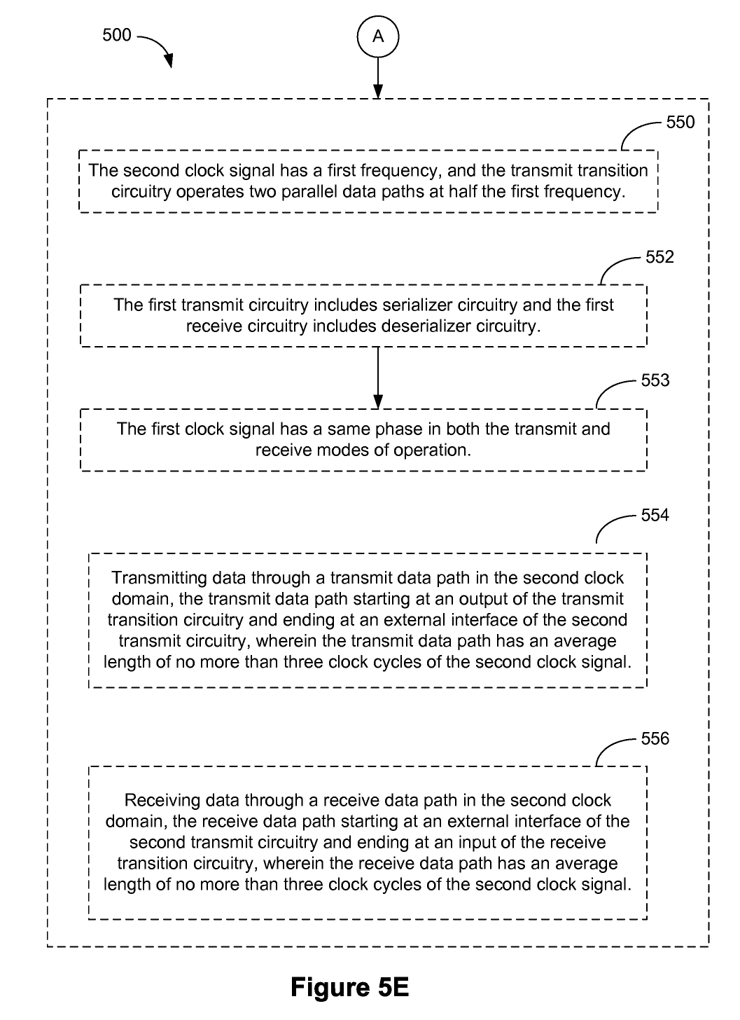

FIGS. 5A-5E are flow diagrams illustrating a process 500 for increasing skip margin in a bit slice circuit with transmit and receive modes of operation in accordance with some embodiments. As shown in FIG. 5A, the process 500 includes receiving a first clock signal (e.g., sclk, FIG. 2A) at a first transmit circuitry (e.g., transmit circuitry 210, FIG. 2A) and a first receive circuitry (e.g., receive circuitry 240, FIG. 2A) 502. The first transmit circuitry and the first receive circuitry operate in a first time domain. In some embodiments, the first transmit circuitry includes serializer circuitry (e.g., serializer 216, FIG. 2A) and the first receive circuitry include deserializer circuitry (e.g., deserializer 246, FIG. 2A) 504. In some embodiments, the first clock signal has a same phase in both transmit and receive modes of operation 506.

A second clock signal (e.g., dclk, FIG. 2A) is generated with a single phase mixer (e.g., phase mixer 204, FIG. 2A) 508. The second clock signal has a first phase in the transmit mode of operation and second phase in the receive mode of operation.

Transmit transition circuitry (e.g., transmit transition circuitry 220, FIG. 2A) and receive transition circuitry (e.g., receive transition circuitry 250, FIG. 2A) receive the first and second clock signals 510. The transmit transition circuitry couples the first transmit circuitry to a second transmit circuitry (e.g., transmit circuitry 230, FIG. 2A), and the receive transition circuitry couples the first receive circuitry to a second receive circuitry (e.g., receive circuitry 260, FIG. 2A). In some embodiments, the second clock signal has a first frequency and the transmit transition circuitry includes two parallel data paths operating at half the first frequency 512.

The second clock signal is received at the second transmit circuitry and the second receive circuitry 514. The second transmit circuitry and the second receive circuitry operate in a second time domain.

In some embodiments, as shown in FIG. 5B, the transmit transition circuitry and the receive transition circuitry each include a skip circuit 520. In some embodiments, the skip circuit has a first memory element (e.g., first memory element 304, FIG. 3A) responsive to the second clock signal, a second memory element (e.g., second memory element 316, FIG. 3A) responsive to the second clock signal, and a multiplexer (e.g., multiplexer 314, FIG. 3A) logically positioned between the first memory element and the second memory element 522. In some embodiments, the first memory element is responsive to a clock signal synchronous with the first clock signal and the second memory element is responsive to a clock signal synchronous with the second clock signal 524.

In some embodiments, transmit data is transmitted through a transmit path in the second clock domain 526 (FIG. 5C). The transmit path starts at an output of the transmit transition circuitry and ends at an external interface of the second transmit circuitry (e.g., transmit memory interface 268, FIG. 2A). Further, the transmit path has an average length of no more than three clock cycles of the second clock signal.

In some embodiments, receive data is received through a receive path in the second clock domain 528 (FIG. 5C). The receive path starts at an external interface of the second receive circuitry (e.g., receive memory interface 270, FIG. 2A) and ends at an output of the receive transition circuitry. Further, the receive path has an average length of no more than three clock cycles of the second clock signal.

In some embodiments, the process further includes the operations described in FIG. 5D. A first digital value corresponding to a phase of the first clock signal is stored in a first circuit 530. A second digital value corresponding to a phase of the second clock signal is stored in a second circuit 532. Logic coupled to the first circuit and the second circuit produces control signals for the transmit transition circuitry 534. In some embodiments, the control signals are produced in accordance with a phase difference between the first clock signals and the second clock signal 536. In some embodiments, the logic is configured to automatically recover from changes in phase of the second clock signal 538.

In some embodiments, the process further includes the operations described in FIG. 5E, where the second clock signal has a first frequency, and the transmit transition circuitry operates two parallel data paths at half the first frequency 550. In some embodiments the first transmit circuitry includes serializer circuitry and the first receive circuitry includes deserializer circuitry 552, and further the first clock signal has a same phase in both the transmit and receive modes of operation 553. In some embodiments the process includes transmitting data through a transmit data path in the second clock domain, the transmit data path starting at an output of the transmit transition circuitry and ending at an external interface of the second transmit circuitry, wherein the transmit data path has an average length of no more than three clock cycles of the second clock signal 554. In some embodiments the process includes receiving data through a receive data path in the second clock domain, the receive data path starting at an external interface of the second transmit circuitry and ending at an input of the receive transition circuitry, wherein the receive data path has an average length of no more than three clock cycles of the second clock signal 556.

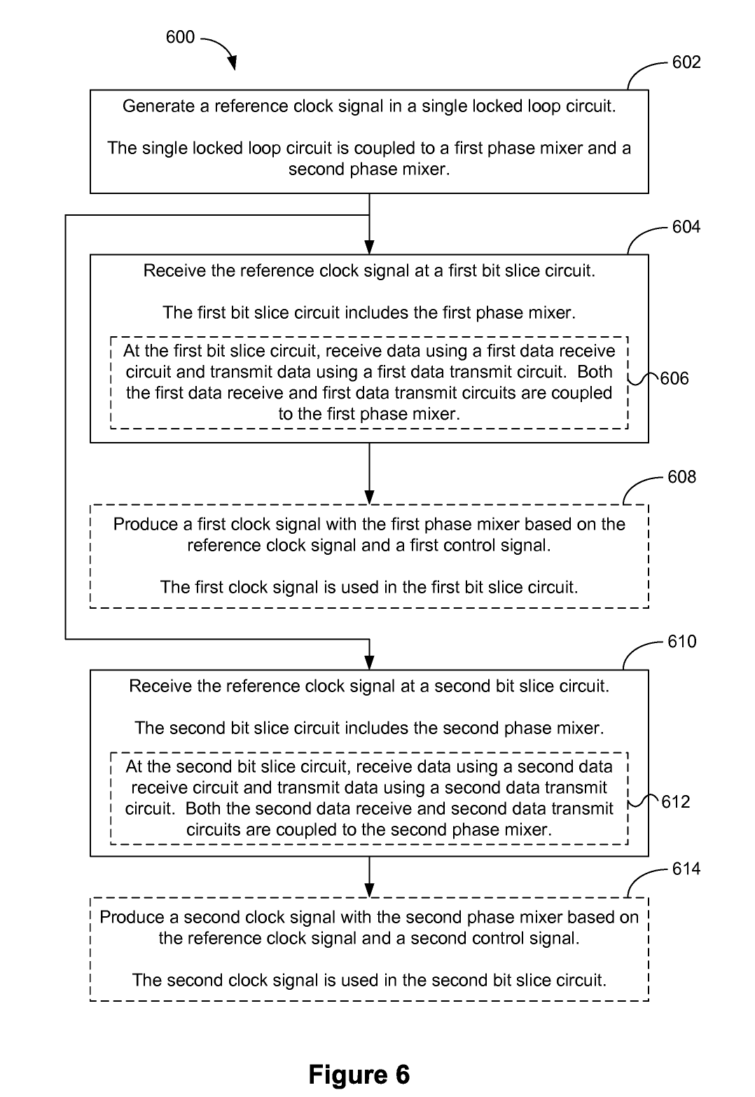

FIG. 6 is a flow diagram illustrating a process 600 of increasing skip margin in a bidirectional memory interface in accordance with some embodiments. As shown in FIG. 6, the process 600 includes generating a reference clock signal (e.g., pll_clk1, FIG. 1B) in a single locked loop circuit (e.g., locked loop circuit 152, FIG. 1B) 602. The single locked loop circuit is coupled to a first phase mixer (e.g., phase mixer 158, FIG. 1B) and a second phase mixer (e.g., phase mixer 176).

The reference clock signal is received at a first bit slice circuit (e.g., bit slice 154a, FIG. 1A) that includes the first phase mixer 604. In some embodiments, the first bit slice circuit receives data using a first data receive circuit and transmits data using a first data transmit circuit. Both the first data receive circuit and the first data transmit circuit are coupled to the first phase mixer. In some embodiments, a first clock signal (e.g., dclk<0>, FIG. 1B) is produced with the first phase mixer based on the reference clock signal and a first control signal 608. The first clock signal is used in the first bit slice circuit.

The reference clock signal is also received at a second bit slice circuit (e.g., bit slice 154b, FIG. 1A) that includes the second phase mixer 610. In some embodiments, the process 600 includes performing operations 610 and 604 in parallel. In some embodiments, the second bit slice circuit receives data using a second data receive circuit and transmits data using a second data transmit circuit (612). Both the second data receive circuit and the second data transmit circuit are coupled to the second phase mixer (612). In some embodiments, a second clock signal (e.g., dclk<1>, FIG. 1B) is produced with the second phase mixer based on the reference clock signal and a second control signal 608. The second clock signal is used in the second bit slice circuit (614).

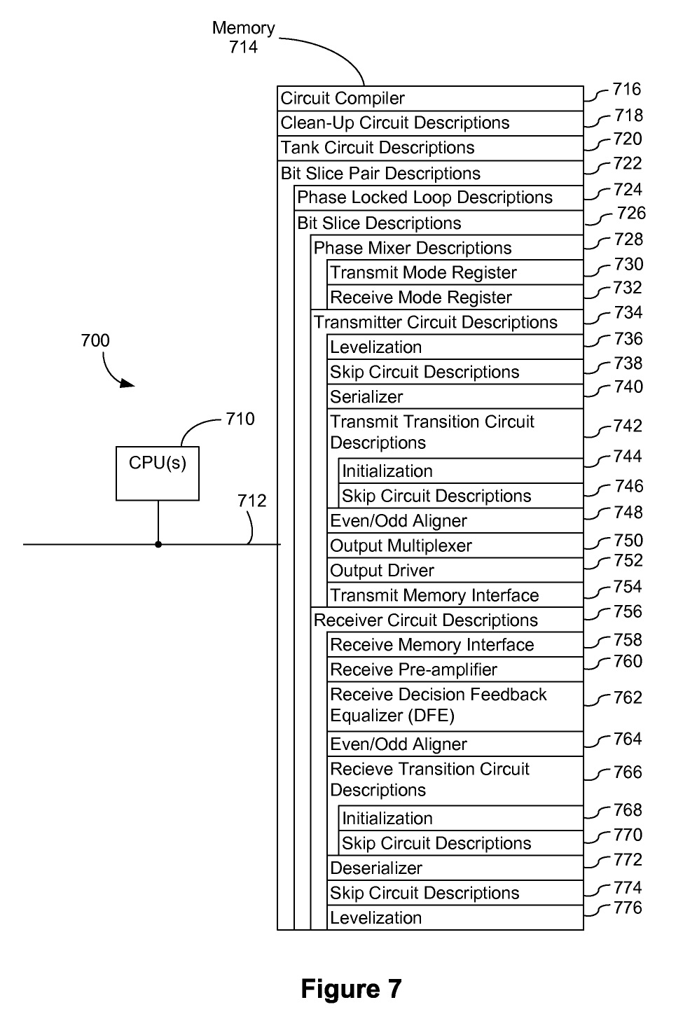

FIG. 7 is a block diagram of an embodiment of a system 700 for storing computer readable files containing software descriptions of circuits for implementing a bidirectional memory interface in accordance with some embodiments. The system 700 may include at least one data processor or central processing unit (CPU) 710, memory 714, and one or more signal lines or communication busses 712 for coupling these components to one another. Memory 714 includes high-speed random access memory, such as DRAM, SRAM, DDR RAM, MRAM or other random access solid state memory devices; and may include non-volatile memory, such as one or more magnetic disk storage devices, optical disk storage devices, flash memory devices, or other non-volatile solid state storage devices. Memory 714 may optionally include one or more storage devices remotely located from the CPU(s) 710.

In some embodiments, memory 714 stores in one or more of the previously mentioned memory devices a circuit compiler 716, clean-up circuit descriptions 718, tank circuit descriptions 720, and bit slice pair descriptions 722. The circuit compiler 716, when executed by a processor such as CPU 710, processes one or more circuit descriptions to synthesize one or more corresponding circuits.

In some embodiments, the bit slice pair descriptions 722 include phase locked loop descriptions 724, and one or more bit slice descriptions 726. In some embodiments, the one or more bit slice descriptions 726 include phase mixer descriptions 728, transmitter circuit descriptions 734, and receiver circuit descriptions 756. In some embodiments, the transmitter circuit descriptions 734 and the receiver circuit descriptions 756 are arranged in parallel.

In some embodiments, the phase mixer circuit descriptions 728 include a transmit mode register 730 and a receive mode register 732.

In some embodiments, the transmitter circuit descriptions 734 include levelization circuit descriptions 736, skip circuit descriptions 738, serializer circuit descriptions 740, transmit transition circuit descriptions 742, even/odd aligner 748, output multiplexer 750, output driver 752, and transmit memory interface 754. In some embodiments, the transmit transition circuit descriptions 742 include initialization 744, and skip circuit descriptions 746.

In some embodiments, the receiver circuit descriptions 756 include receive memory interface descriptions 758, receive pre-amplifier circuit descriptions 760, receive decision feedback equalizer circuit descriptions 762, even/odd aligner circuit descriptions 764, receive transition circuit descriptions 766, deserializer circuit descriptions 772, skip circuit descriptions 774, and levelization circuit descriptions 776. In some embodiments, the receive transition circuit descriptions 766 include initialization 768, and skip circuit descriptions 770.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

What is claimed is:

1.-42. (canceled)

43. A bit slice circuit having transmit and receive modes of operation, comprising:
first transmit circuitry and first receive circuitry, the first transmit circuitry including serializer circuitry operating in a first clock domain, the first receive circuitry including deserializer circuitry operating in the first clock domain, wherein the serializer and deserializer circuitry receive a first clock signal;
second transmit circuitry and second receive circuitry operating in a second clock domain, wherein the second transmit circuitry and second receive circuitry receive a second clock signal;
transmit transition circuitry and receive transition circuitry to pass data between the first clock domain and the second clock domain, the transmit transition circuitry coupling the first transmit circuitry to the second transmit circuitry, the receive transition circuitry coupling the first receive circuitry to the second receive circuitry, wherein the transmit transition circuitry and receive transition circuitry each receive the first and second clock signals; and
a single phase mixer to generate the second clock signal, wherein the second clock signal has a first phase in the transmit mode of operation and second phase in the receive mode of operation.

44. The circuit of claim 43, wherein the second clock signal has a first frequency, and the transmit transition circuitry includes two parallel data paths operating at half the first frequency.

45. The circuit of claim 43, wherein the first clock signal has a same phase in both the transmit and receive modes of operation.

46. The circuit of claim 43, wherein a transmit data path in the second clock domain, starting at an output of the transmit transition circuitry and ending at an external interface of the second transmit circuitry, has an average length of no more than three clock cycles of the second clock signal.

47. The circuit of claim 43, wherein a receive data path in the second clock domain, starting at an external interface of the second transmit circuitry and ending at an input of the receive transition circuitry, has an average length of no more than three clock cycles of the second clock signal.

48. The circuit of claim 43, including a first circuit storing a first digital value corresponding to a phase of the first clock signal, a second circuit storing a second digital value corresponding to a phase of the second clock signal, and logic coupled to the first circuit and second circuit to produce control signals for the transmit transition circuit.

49. The circuit of claim 48, wherein the control signals are produced in accordance with a phase difference between the first clock signal and second clock signal

50. The circuit of claim 48, wherein the logic is configured to automatically recover from changes in phase of the second clock signal.

51. The circuit of claim 43, wherein the transmit transition circuitry and the receive transition circuitry each include a respective skip circuit.

52. The circuit of claim 51, wherein each respective skip circuit comprises a first memory element responsive to the first clock signal, a second memory element responsive to the second clock signal, and a multiplexer logically positioned between the first memory element and the second memory element.

53. The circuit of claim 51, wherein each respective skip circuit comprises a first memory element responsive to a clock signal synchronous with the first clock signal, a second memory element responsive to a clock signal synchronous with the second clock signal, and a multiplexer logically positioned between the first memory element and the second memory element.

54. A transceiver circuit, comprising
a first bit slice circuit to transmit and receive data, having a first phase mixer to receive a local master clock signal comprising a set of at least four clock phasors and to produce a first clock signal for use in the first bit slice circuit;
a second bit slice circuit to transmit and receive data, having a second phase mixer to receive the local master clock signal comprising the set of at least four clock phasors and to produce a second clock signal for use in the second bit slice circuit; and
a single locked loop circuit, coupled to the first phase mixer and the second phase mixer, to generate the local master clock signal comprising the set of at least four clock phasors.

55. The transceiver circuit of claim 54, wherein
the first bit slice circuit includes a data receive circuit and a data transmit circuit, both coupled to the first phase mixer; and
the second bit slice circuit includes a data receive circuit and a data transmit circuit, both coupled to the second phase mixer.

56. The transceiver circuit of claim 55, wherein the first phase mixer produces the first clock signal for use in the first bit slice circuit based on the local master clock signal and a first control signal; and the second phase mixer produces the second clock signal for use in the second bit slice circuit based on the local master clock signal and a second control signal.

57. The transceiver circuit of claim 54, wherein the transceiver circuit is in an integrated circuit and the single locked loop circuit is positioned between the first bit slice circuit and the second bit slice circuit.

58. The transceiver circuit of claim 54, wherein the transceiver circuit is in an integrated circuit and the single locked loop circuit is positioned symmetrically with respect to the first bit slice circuit and the second bit slice circuit.

59. The transceiver circuit of claim 54, wherein the single locked loop circuit is coupled to a reference clock which controls a frequency of the single locked loop circuit.

60. A transceiver circuit, comprising:
N bit slice pairs, where N is an integer greater than 1, wherein each bit slice pair comprises:
a first bit slice circuit to transmit and receive data, having a first phase mixer to receive a local master clock signal and to produce a first clock signal for use in the first bit slice circuit;
a second bit slice circuit to transmit and receive data, having a second phase mixer to receive the local master clock signal and to produce a second clock signal for use in the second bit slice circuit; and
a single locked loop circuit, coupled to the first phase mixer and the second phase mixer, to generate the local master clock;
wherein the N bit slice pairs transmit 2N bits in parallel, and receive 2N bits in parallel.

61. The transceiver circuit of claim 60, further including
an additional locked loop circuit, having an input to receive a master reference clock signal and an output coupled to the single locked loop circuit in each of the N bit slice pairs.

62. The transceiver circuit of claim 61, wherein the output of the additional locked loop circuit has a frequency that is greater than a frequency of the master reference clock signal.

63. The transceiver circuit of claim 61, wherein the master reference clock signal has a first frequency and the output of the additional locked loop circuit has a second frequency that is a multiple of the first frequency, and wherein the multiple comprises an integer greater one.

64. The transceiver circuit of claim 61, further including
a resonant tank circuit, having an input coupled to the additional locked loop circuit and an output coupled to the single locked loop circuit in each of the N bit slice pairs.

65. The transceiver circuit of claim 64, wherein the resonant tank circuit has a resonant frequency equal to a frequency of the output of the additional locked loop circuit.

66. A method of increasing skip margin in a bit slice circuit with transmit and receive modes of operation, comprising:
receiving a first clock signal at serializer circuitry in first transmit circuitry and deserializer circuitry in first receive circuitry, wherein the serializer and deserializer circuitry operate in a first clock domain;
receiving a second clock signal at second transmit circuitry and second receive circuitry, wherein the second transmit circuitry and second receive circuitry operate in a second clock domain;
receiving the first and second clock signals at transmit transition circuitry and receive transition circuitry, the transmit transition circuitry coupling the first transmit circuitry and second transmit circuitry, the receive transition circuitry coupling the first receive circuitry and second receive circuitry;
generating the second clock signal with a single phase mixer, wherein the second clock signal has a first phase in the transmit mode of operation and second phase in the receive mode of operation;
during the transmit mode of operation:
passing data from the first clock domain to the second clock domain using the transmit transition circuitry, and
transmitting data through a transmit data path in the second clock domain; and
during the receive mode of operation:
receiving data through a receive data path in the second clock domain, and
passing data from the second clock domain to the first clock domain using the receive transition circuitry.

67. The method of claim 66, wherein the bit slice circuit transitions from the transmit mode to the receive mode within half a clock cycle of the second clock signal.

68. The method of claim 66, wherein the second clock signal transitions from the first phase to the second phase within half a clock cycle of the second clock signal.

69. The method of claim 66, wherein the second clock signal has a first frequency, and the transmit transition circuitry operates two parallel data paths at half the first frequency.

70. The method of claim 66, wherein the first clock signal has a same phase in both the transmit and receive modes of operation.

71. The method of claim 66, wherein:
the transmit data path starts at an output of the transmit transition circuitry and ends at an external interface of the second transmit circuitry, and
the transmit data path has an average length of no more than three clock cycles of the second clock signal.

72. The method of claim 66, wherein:
the receive data path starts at an external interface of the second transmit circuitry and ends at an input of the receive transition circuitry, and
the receive data path has an average length of no more than three clock cycles of the second clock signal.

73. The method of claim 66, including
storing a first digital value corresponding to a phase of the first clock signal in a first circuit;
storing a second digital value corresponding to a phase of the second clock signal in a second circuit; and
producing control signals for the transmit transition circuitry in logic coupled to the first circuit and second circuit.

74. The method of claim 73, wherein the control signals are produced in accordance with a phase difference between the first clock signal and second clock signal.

75. The method of claim 73, wherein the logic is configured to automatically recover from changes in phase of the second clock signal.

76. The method of claim 75, wherein the second clock signal transitions from the first phase to the second phase within half a clock cycle of the second clock signal.

77. The method of claim 66, wherein the transmit transition circuitry and receive transition circuitry each includes a skip circuit.

78. The method of claim 77, wherein the skip circuit comprises a first memory element responsive to the first clock signal, a second memory element responsive to the second clock signal, and a multiplexer logically positioned between the first memory element and the second memory element.

79. The method of claim 77, wherein the skip circuit comprises a first memory element responsive to a clock signal synchronous with the first clock signal, a second memory element responsive to a clock signal synchronous with the second clock signal, and a multiplexer logically positioned between the first memory element and the second memory element.

80. A method of increasing skip margin in a bidirectional memory interface, comprising:
generating a local master clock signal in a single locked loop circuit, the single locked loop circuit coupled to a first phase mixer and a second phase mixer;
receiving the local master clock signal at a first bit slice circuit, the first bit slice circuit comprising the first phase mixer;
receiving the local master clock signal at a second bit slice circuit, the second bit slice circuit comprising the second phase mixer;
at the first bit slice circuit, receiving data using a first data receive circuit and transmitting data using a first data transmit circuit, both coupled to the first phase mixer; and
at the second bit slice circuit, receiving data using a second data receive circuit and transmitting data using a second data transmit circuit, both coupled to the second phase mixer.

81. The method of claim 80, including
producing a first clock signal at the first phase mixer for use in the first bit slice based on the local master clock signal and a first control signal; and
producing a second clock signal at the second phase mixer for use in the second bit slice based on the local master clock signal and a second control signal.
